(19) United States
(12) Patent Application Publication
(10) Pub. No.: US 2024/0413156 A1
(43) Pub. Date: Dec. 12, 2024

(54) CFETs and the Methods of Forming the Same

(71) Applicant: Taiwan Semiconductor Manufacturing Co., Ltd., Hsinchu (TW)

(72) Inventors: Ting-Yun Wu, Taipei City (TW); Jui-Chien Huang, Hsinchu (TW); Szuya Liao, Zhubei (TW)

(21) Appl. No.: 18/503,892

(22) Filed: Nov. 7, 2023

Related U.S. Application Data
(60) Provisional application No. 63/507,205, filed on Jun. 9, 2023.

(51) Int. Cl. H01L 27/092; H01L 21/822; H01L 21/8238; H01L 29/06; H01L 29/417; H01L 29/423; H01L 29/66; H01L 29/775

(52) U.S. Cl. CPC H01L 27/0922; H01L 21/8221; H01L 21/823871; H01L 29/0673; H01L 29/41733; H01L 29/42392; H01L 29/66439; H01L 29/775

(57) ABSTRACT

A method includes forming a lower transistor in a lower wafer, wherein the lower transistor includes a lower source/drain region, forming a contact plug electrically connecting to the lower source/drain region, and forming a metal line over the lower transistor. A first portion of the metal line is vertically aligned to the lower source/drain region. The method further includes bonding an upper wafer to the lower wafer, and forming an upper transistor in the upper wafer. The upper transistor includes an upper source/drain region, and is vertically aligned to a second portion of the metal line. A first interconnect structure is formed on the lower wafer and electrically connecting to the lower transistor. A second interconnect structure is formed on the upper wafer and electrically connecting to the upper transistor.

### PRIORITY CLAIM AND CROSS-REFERENCE

This application claims the benefit of the following provisionally filed U.S. Patent application: Application No. 63/507,205, filed on Jun. 9, 2023, and entitled “CFET Scheme Options,” which application is hereby incorporated herein by reference.

### BACKGROUND

Complementary Field-Effect Transistors (CFETs) are being developed to meet the increasing demanding requirement for increasing the density of transistors in integrated circuits. CFETs are thus developed. A CFET includes a lower transistor and an upper transistor overlapping the lower transistor. The lower transistors and upper transistors of multiple CFETs may be interconnected through local interconnect structures to form functional circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1N, 2A-2G, 3A-3J, 4A-4L, 5A-5I, and 6A-6I illustrate the views of the formation of CFETs through sequential formation processes in accordance with some embodiments.

FIG. 7 illustrates a process flow for forming CFETs through a sequential formation process in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) including upper transistors and lower transistors are provided. The local interconnects for interconnecting the upper Field-Effect Transistors (FETs, alternatively referred to as transistors hereinafter) and the lower transistors and the methods of forming the local interconnects are provided. In accordance with some embodiments, the CFETs are formed through sequential or parallel processes. This provides the flexibility in the materials and the structures of the upper transistors and the lower transistors. For example, the upper transistors and the lower transistors may be formed on semiconductor materials having different surface orientations. Also, the upper transistors and the lower transistors may have different structures such as different number of nanosheets. The upper transistors and the lower transistors may also be selected from Gate-All-Around (GAA) transistors and Fin Field-Effect Transistors (FinFETs).

Although the example embodiments provide specific combinations of GAA transistors and FinFETs as the upper transistors and the lower transistors, other combinations different from the example embodiments are also in the scope of the present disclosure. The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

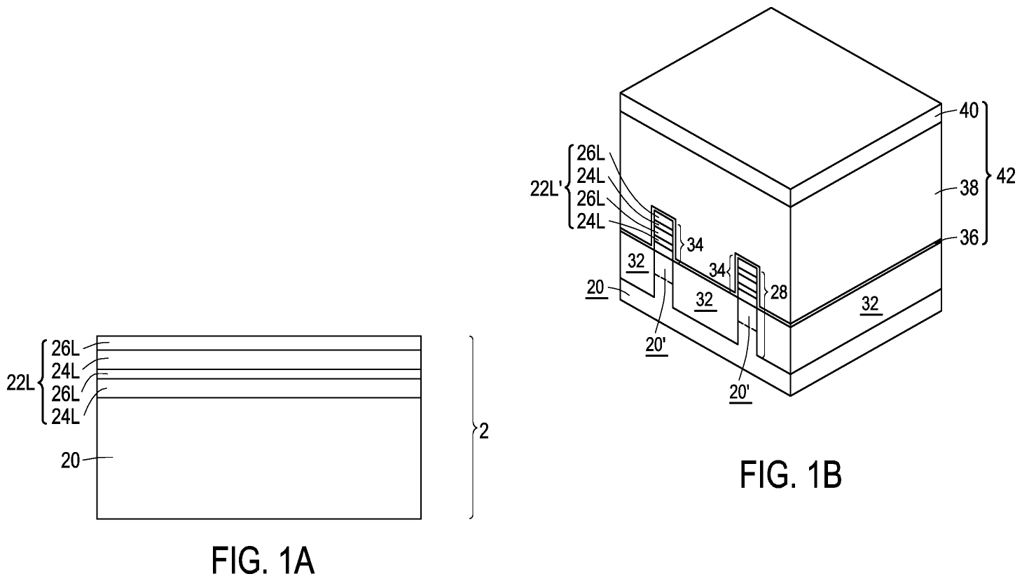

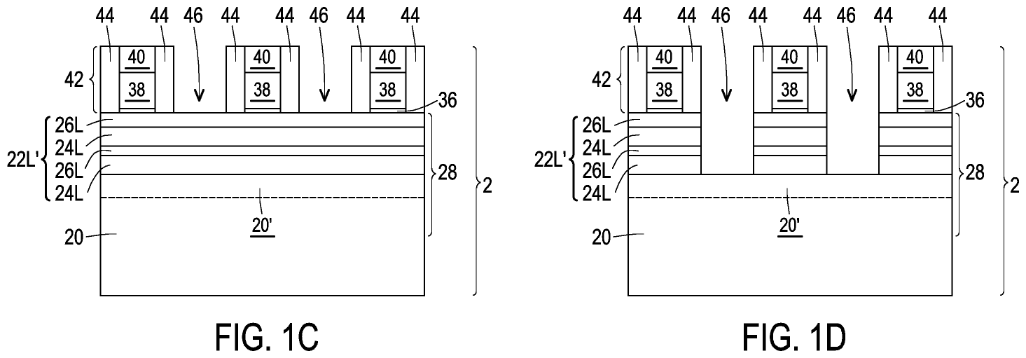

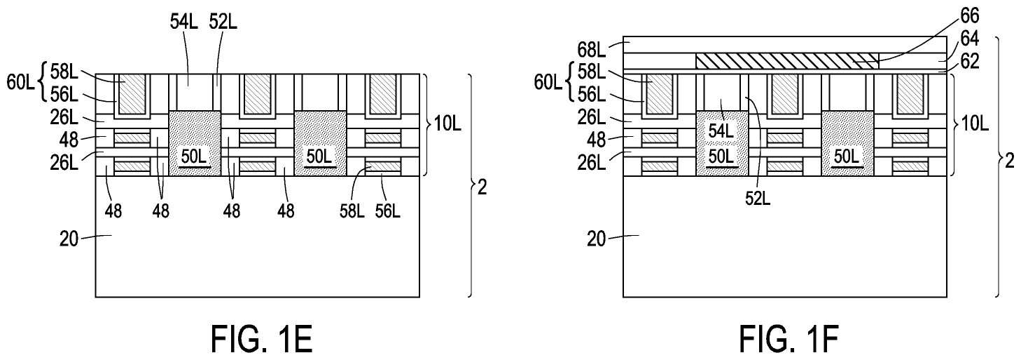

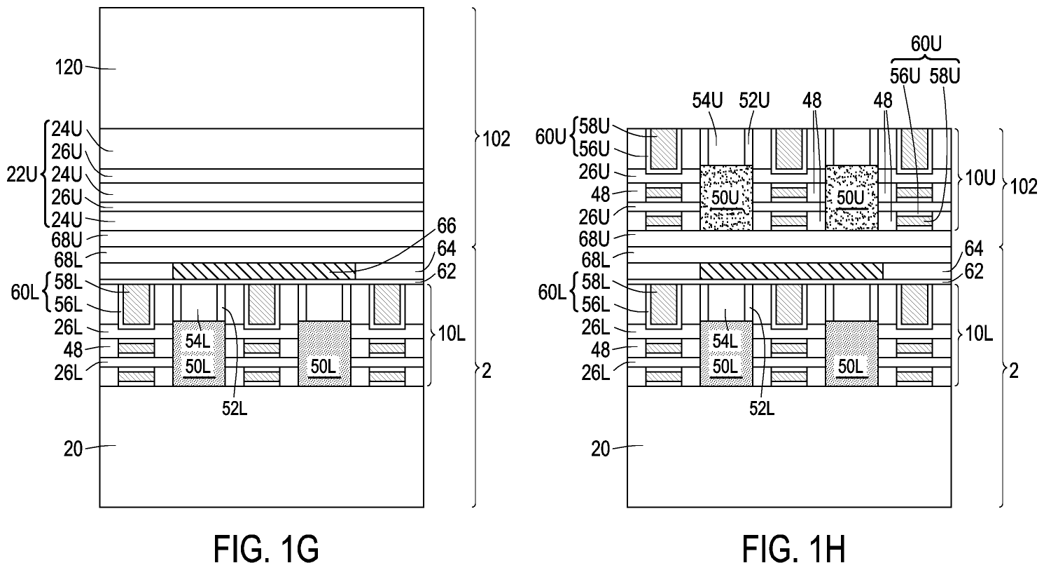

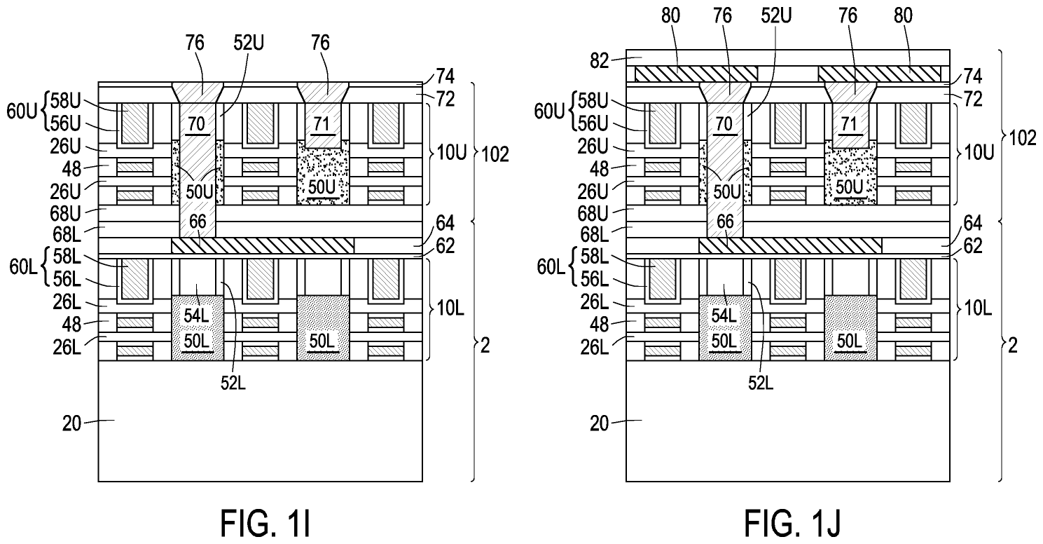

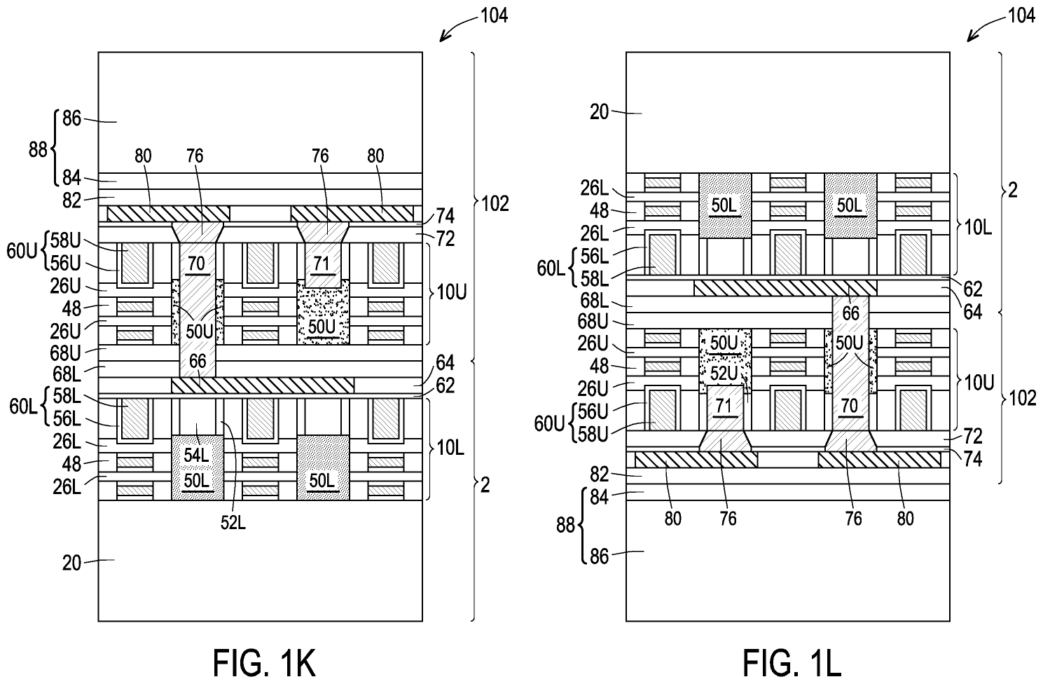

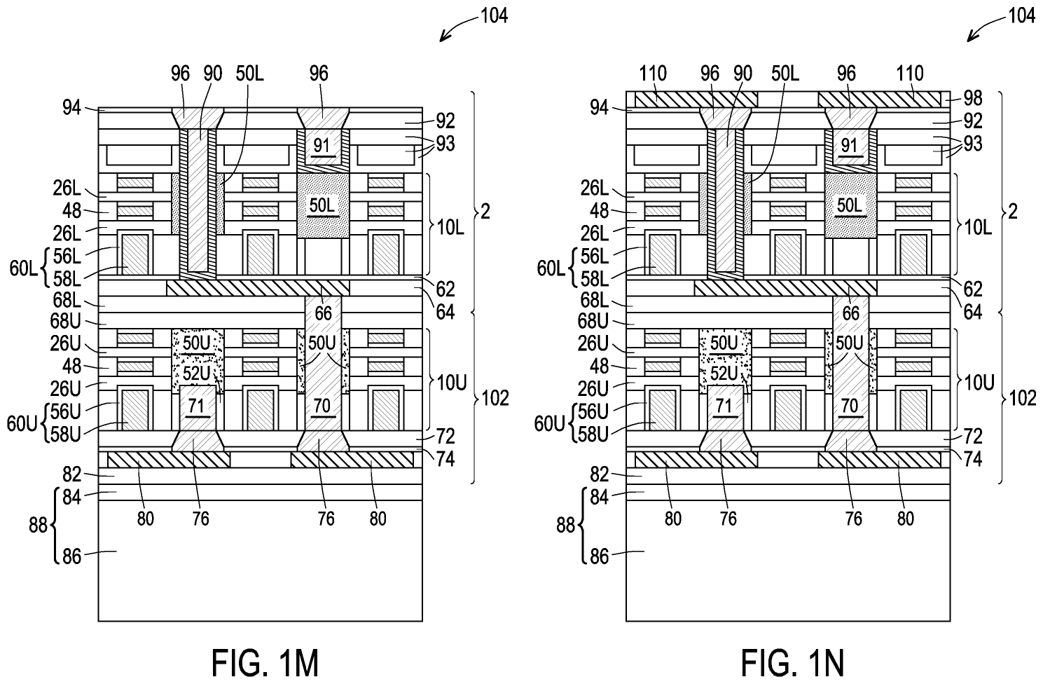

FIGS. 1A-1N, 2A-2G, 3A-3J, 4A-4L, 5A-5I, and 6A-6I illustrate the views of the formation of CFETs through sequential processes in accordance with some embodiments. In the sequential formation processes, lower transistors are formed first, followed by the formation of the upper transistors.

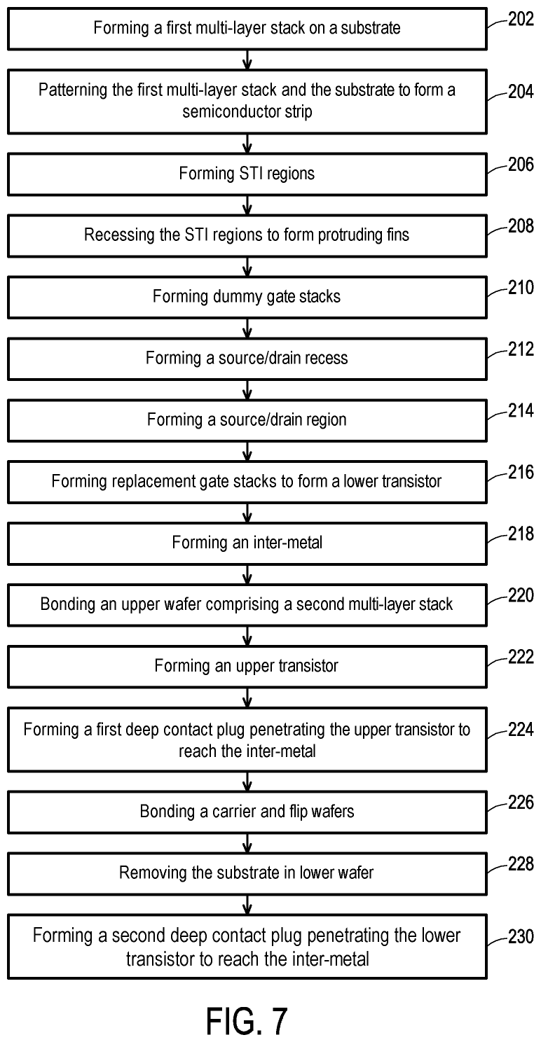

FIGS. 1A-1N illustrate the cross-sectional views of intermediate stages in the formation of CFETs and local interconnects in accordance with some embodiments of the present disclosure. The corresponding processes are also reflected schematically in the process flow 200 as shown in FIG. 7. The corresponding bonding process is also referred to as a face-to-back process since the front side (the face) of the bottom transistors (and the bottom die/wafer) is bonded to the backside of the upper transistors (and the upper die/wafer).

Referring to FIG. 1A, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. In accordance with some embodiments, the semiconductor material of the substrate 20 may include silicon, germanium, carbon-doped silicon, a III-V compound semiconductor; or the like, or combinations thereof.

A multi-layer stack 22L is formed over the substrate 20. The respective process is illustrated as process 202 in the process flow 200 as shown in FIG. 7. The multi-layer stack 22 includes alternating dummy semiconductor layers 24L and semiconductor layers 26L. Lower semiconductor layers 26L are for forming a lower transistor. Appropriate well regions (not separately illustrated) such as p-well regions and n-well regions may be formed in lower semiconductor nanostructures 26L. For example, semiconductor nanostructures 26L may be in-situ doped (when epitaxially grown) and/or implanted to n-type when the lower transistors to be formed are p-type transistors. Conversely, semiconductor nanostructures 26L may be of p-type when the lower transistors to be formed are n-type transistors.

In the illustrated example, two dummy semiconductor layers 24L and two semiconductor layers 26L are illustrated as an example, while the total numbers of these layers may be greater than 2, such as 3, 4, 5, or more, depending on the desirable performance requirement of the lower transistors. In accordance with some embodiments, the (top) surface orientation of semiconductor layers 26L is selected based on the type of the lower transistors, so that the performance of the lower transistors is improved. For example, when the lower transistors are p-type transistors, the (top) surface orientation may be (110). Conversely, when the lower transistors are n-type transistors, the (top) surface orientation may be (100).

The dummy semiconductor layers 24L may be formed of a first semiconductor material. The semiconductor layers 26L are formed of a second semiconductor material different from the first semiconductor material. In accordance with some embodiments, dummy semiconductor layers 24L are formed of or comprise silicon germanium, and semiconductor layers 26 may be formed of silicon.

Multi-layer stack 22L and substrate 20 are patterned to form semiconductor strips 28 as shown in FIG. 1B, which illustrates a perspective view. The respective process is illustrated as process 204 in the process flow 200 as shown in FIG. 7. Each of semiconductor strips 28 includes a semiconductor strip 20′ (the portions of the original substrate 20) and multi-layer stack 22L′, which is a remaining portion of multi-layer stack 22L. The layers in the remaining portions 22L′ may be referred to as nanostructures hereinafter. The etching may be performed by any acceptable etch process, such as a Reactive Ion Etch (RIE), Neutral Beam Etch (NBE), the like, or a combination thereof. The etching may be anisotropic. The remaining portions of the lower semiconductor nanostructures 26L will act as channel regions for the lower transistors of the CFETs.

Isolation regions 32 are formed over the substrate 20 and between adjacent semiconductor strips 28. The respective process is illustrated as process 206 in the process flow 200 as shown in FIG. 7. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of isolation regions 32 may include depositing the dielectric layer(s), and performing a planarization process such as a Chemical Mechanical Polish (CMP) process, a mechanical polishing process, or the like to remove excess portions of the dielectric materials. The deposition processes may include chemical vapor deposition (CVD), atomic layer deposition (ALD), HDP-CVD, FCVD, the like, or a combination thereof. In accordance with some embodiments, the isolation regions 32 include silicon oxide formed by an FCVD process, followed by an anneal process.

After the planarization process, isolation regions 32 are recessed. Some upper portions of semiconductor strips 28 (including multi-layer stacks 22L′) protrude higher than the remaining isolation regions 32 to form protruding fins 34. The respective process is also illustrated as process 208 in the process flow 200 as shown in FIG. 7.

Dummy gate dielectric 36 is formed on the protruding fins 34. Dummy gate dielectric 36 may be formed of or comprise, for example, silicon oxide, silicon nitride, a combination thereof, or the like, and may be deposited or thermally grown according to acceptable techniques. A dummy gate layer 38 is formed over the dummy gate dielectric 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. One or more mask layer(s) 40 is formed over the planarized dummy gate layer 38, and may include, for example, silicon nitride, silicon oxynitride, or the like.

Next, the mask layer 40 may be patterned through photolithography and etching processes to form a mask, which is then used to etch and pattern dummy gate layer 38, and possibly dummy gate dielectric 36. A resulting structure is shown in FIG. 1C, which illustrates a vertical cross-section in FIG. 1B, which vertical cross-section is along the lengthwise direction of semiconductor strip 28. The remaining portions of mask layer 40, dummy gate layer 38, and dummy gate dielectric 36 form dummy gate stacks 42 as shown in FIG. 1C. The respective process is illustrated as process 210 in the process flow 200 as shown in FIG. 7.

Gate spacers 44 are then formed over the multi-layer stacks 22L′ and on the exposed sidewalls of dummy gate stacks 42. The gate spacers 44 may be formed by conformally depositing one or more dielectric layers and subsequently etching the dielectric layers in anisotropic etching processes. The applicable dielectric materials may include silicon oxide, silicon nitride, silicon oxynitride, silicon oxycarbonitride, or the like, which may be formed by a deposition process such as CVD, ALD, or the like.

Referring to FIG. 1D, source/drain recesses 46 are formed in semiconductor strips 28. The respective process is also illustrated as process 212 in the process flow 200 as shown in FIG. 7. The source/drain recesses 46 are formed through etching, and may extend through the multi-layer stacks 22L′, and may or may not extend into the semiconductor strips 20′. The bottom surfaces of the source/drain recesses 46 may be at a level above, below, or level with the top surfaces of the isolation regions 32 (not shown in FIG. 1D). In the etching processes, the gate spacers 44 and the dummy gate stacks 42 cover and hence protect some portions of the semiconductor strips 28. The etching may include a single etch process or multiple etch processes. Timed etch processes may be used to stop the etching of the source/drain recesses 46 upon source/drain recesses 46 reaching a desired depth.

In FIG. 1E, inner spacers 48 are formed. The formation of inner spacers 48 may include an etching process that laterally etches the dummy semiconductor layers 24L (FIG. 1D), and filling the respective lateral recesses with a dielectric material to form the inner spacers 48.

The etching process may be isotropic and may be selective to the material of the dummy semiconductor layers 24L, so that the dummy semiconductor layers 24L are etched at a faster rate than the semiconductor nanostructures 26L. In accordance with some embodiments in which the dummy nanostructures 24L are formed of silicon germanium or germanium, and the semiconductor nanostructures 26L are formed of silicon free from germanium, the etch process may comprise a dry etch process using chlorine gas, with or without a plasma.

Inner spacers 48 are formed on the sidewalls of the laterally recessed dummy semiconductor layers 24L. In the subsequent formation of source/drain regions, the inner spacers 48 may act as isolation features between the subsequently formed source/drain regions and the subsequently formed gate structures. Further, the inner spacers 48 may be used to prevent damage to the subsequently formed source/drain regions by subsequent etch processes, such as the etch processes used to form gate structures.

The formation of the inner spacers 48 may include conformally depositing a dielectric insulating material in the source/drain recesses 46, and then etching the dielectric insulating material. The dielectric insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic.

Further referring to FIG. 1E, lower epitaxial source/drain regions 50L are formed. The respective process is illustrated as process 214 in the process flow 200 as shown in FIG. 7. The lower epitaxial source/drain regions 50L are in contact with the lower semiconductor nanostructures 26L. Inner spacers 48 electrically insulate the lower epitaxial source/drain regions 50L from the dummy semiconductor layers 24L, which will be replaced with replacement gates in subsequent processes.

The lower epitaxial source/drain regions 50L are epitaxially grown, and have a conductivity type that is suitable for the device type (p-type or n-type) of the lower transistors. When lower epitaxial source/drain regions 50L are n-type source/drain regions, the respective material may include silicon or carbon-doped silicon, which is doped with an n-type dopant such as phosphorous, arsenic, and/or the like. When lower epitaxial source/drain regions 50L are p-type source/drain regions, the respective material may include silicon or silicon germanium, which is doped with a p-type dopant such as boron, indium, and/or the like. The lower epitaxial source/drain regions 50L may be in-situ doped, and may be, or may not be, implanted with the corresponding p-type or n-type dopants.

A first Contact Etch Stop Layer (CESL) 52L and a first Inter-Layer Dielectric (ILD) 54L are formed over the lower epitaxial source/drain regions 50L. In accordance with some embodiments, CESL 52L may include vertical portions (as illustrated) and horizontal portions (not shown) that are directly on the lower epitaxial source/drain regions 50L. In accordance with alternative embodiments, the horizontal portions of the CESL 52L are removed prior to the formation of the first ILD 54L.

The first CESL 52L may be formed of a dielectric material having a high etching selectivity from the etching of the first ILD 54L, such as silicon nitride, silicon oxide, silicon oxynitride, or the like, which may be formed by any suitable deposition process, such as CVD, ALD, or the like. The first ILD 54L may be formed of a dielectric material, which may be deposited by any suitable method, such as CVD, plasma-enhanced CVD (PECVD), or FCVD. The applicable dielectric material of the first ILD 54L may include phospho-silicate glass (PSG), boro-silicate glass (BSG), boron-doped phospho-silicate glass (BPSG), undoped silicate glass (USG), silicon oxide, or the like. The top surfaces of the first CESL 52L, the first ILD 54L, and the dummy gate stacks 42 (FIG. 1D) may be planarized by a planarization process, which may be a Chemical Mechanical Polish (CMP) process or a mechanical polishing process.

Further referring to FIG. 1E, replacement gate stacks 60L are formed, which include gate dielectrics 56L and gate electrodes 58L. The respective process is illustrated as process 216 in the process flow 200 as shown in FIG. 7. Gate dielectrics 56L may be conformally formed on the channel regions of the semiconductor nanostructures 26. Each of the gate dielectrics 56L may include an interfacial layer (IL), which may be formed of or comprise an oxide such as silicon oxide or a metal oxide, a silicate such as a metal silicate, combinations thereof, multi-layers thereof, or the like. Each of the gate dielectrics 56L may also include a high dielectric constant (high-k) dielectric layer formed of a high-k dielectric material having a k-value greater than 3.9, and possibly greater than about 7.0. The high-k dielectric material may comprise a metal oxide or a metal nitride of metals such as hafnium, aluminum, zirconium, lanthanum, manganese, barium, titanium, lead. The formation methods of the gate dielectrics 56L may include molecular-beam deposition (MBD), ALD, PECVD, and the like.

Further referring to FIG. 1E, lower gate electrodes 58L are formed on the gate dielectrics 56L, and also wrap around the lower semiconductor nanostructures 26L. Lower gate electrodes 58L may include adhesion layers, work-function layers, a filling metal, or the like. The materials of the work-function layers are selected based on the conductivity type of the respective transistor. For example, for an n-type transistor, n-type work function materials such as TiAl, TiAIN, or the like may be used to form the work-function layer. For a p-type transistor, p-type work function materials such as TiN may be used to form the work-function layer. Lower transistor 10L is thus formed.

FIG. 1F illustrates the formation of etch stop layer 62, dielectric layer 64, and metal line 66 in accordance with some embodiments. Metal line 66 is also referred to as an inter-metal since it is formed between the lower transistor 10L and the subsequently formed upper transistor. The respective process is illustrated as process 218 in the process flow 200 as shown in FIG. 7.

In accordance with some embodiments, etch stop layer 62 is formed of a dielectric material such as AlN, AIO, SION, SiOC, SiCN, or the like, or multi-layers thereof. Etch stop layer 62 may be used to stop the etching from both the top side (when forming metal line 66) and the bottom side (when forming deep contact plug 90, FIG. 1M). In accordance with some embodiments, etch stop layer 62 may have a symmetric multi-layer structure, which may include a top layer and a bottom layer formed of a same material (such as an AlN, AlO, or AlON), and a middle layer between the top layer and the bottom layer, with the middle layer having a high etching selectivity from the top layer and the bottom layer. For example, the middle layer may be formed of SiOC, SiON, or the like. The symmetric structure will increase the ability of the etch stop layer 62 for stop etching when etching from both the top side and the bottom side.

Dielectric layer 64 may be formed of a dielectric material such as silicon oxide, PSG, BSG, BPSG, USG, or the like. Metal line 66 may be formed of copper, tungsten, nickel, TiN, Ti, Ta, TiN, or the like. For example, metal line 66 may have a damascene structure, which is formed by etching dielectric layer 64 (and stopping on etch stop layer 62), filling a conductive material into the respective trench, and performing a planarization process. Metal line 66 may include an adhesion layer (formed of Ti, TiN, Ta, TaN, or the like), and a metallic material such as copper on the adhesion layer.

Bond layer 68L is then deposited. In accordance with some embodiments, bond layer 68L is formed through a deposition process such as CVD, ALD, PECVD, or the like. A planarization process may be performed to level the top surface of bond layer 68L. In accordance with some embodiments, bond layer 68L is formed of or comprises a silicon-containing dielectric material selected from SiO, SiC, SiN, SiOC, SiON, SiOCN, SiCN, or the like. Wafer 2 is thus prepared for bonding.

Referring to FIG. 1G, wafer 102 is bonded to wafer 2. The respective process is illustrated as process 220 in the process flow 200 as shown in FIG. 7. Wafer 102 may include substrate 120, multi-layer stack 22U, and bond layer 68U. Multi-layer stack 22U includes alternating semiconductor layers 26U and dummy semiconductor layers 24U. The alternating layers of semiconductor nanostructures 26U and dummy semiconductor layers 24U may be epitaxially grown in a plurality of epitaxy processes, each forming one of semiconductor nanostructures 26U and dummy semiconductor layers 24A.

The materials and the formation processes of substrate 120 and multi-layer stack 22U may be essentially the same as that of substrate 20 and multi-layer stack 22L as shown in FIG. 1, and the details are not repeated herein. The top layer of multi-layer stack 22U may be a dummy semiconductor layer 24U, which may be formed of silicon germanium in accordance with some embodiments. Bond layer 68U is formed on multi-layer stack 22U, and may also be formed of or comprise a silicon-containing dielectric material such as silicon oxide, silicon nitride, silicon oxynitride, silicon oxycarbide, silicon oxy carbonitride, or the like.

Upper wafer 102 is flipped upside down, and is bonded to the underlying lower wafer 2 through the bonding of bond layer 68U to bond layer 68L. The resulting composite wafer is shown in FIG. 1G. The bonding of bond layer 68U to bond layer 68L may be achieved through fusion bonding, for example, with Si—O—Si bonds being formed to join bond layer 68U to bond layer 68L.

Next, substrate 120 is removed, for example, through a smart cut process (to remove a majority portion of substrate 120), a CMP process, a mechanical grinding process, and/or an anisotropic etching process. The top one of the dummy semiconductor layers 24U may act as an etch stop layer. Accordingly, after an etching process or a polishing process, the top one of the dummy semiconductor layers 24U is exposed.

Next, the top dummy semiconductor layer 24U is removed in an etching process, which may be anisotropic or isotropic. The etching is performed using an etching chemical (a gas or a wet etching solution) that etches dummy semiconductor layer 24U faster than etching semiconductor nanostructures 26U. Accordingly, the top one of semiconductor nanostructures 26U acts as the etch stop layer.

In subsequent processes, as shown in FIG. 1H, upper transistor 10U is formed, with the semiconductor nanostructures 26U forming the channels of upper transistors 10U. The respective process is illustrated as process 222 in the process flow 200 as shown in FIG. 7. The formation process may be essentially the same as the formation of lower transistor 10L, which formation processes have been discussed referring to FIGS. 1B through 1E, and the details are not repeated herein.

The upper transistor 10U may include inner spacers 48, source/drain regions 50U, CESL 52U, and ILD 54U. Furthermore, gate stacks 60U are formed, and include gate dielectrics 56U and gate electrodes 58U. Transistor 10U may have an opposite conductivity type than transistor 10L. The conductivity type of source/drain regions 50U may also be opposite to that of source/drain regions 50L.

It is appreciated that although both of the lower transistor 10L and upper transistor 10U are GAA transistors in the example embodiments as illustrated, each of them may also be a FinFET or a GAA transistor (such as a nanosheet transistor or a nanowire transistor) in any combination.

FIG. 1I illustrates the formation of deep contact plug 70, which acts as both of the source/drain contact plug and the deep via connecting to the metal line 66. The respective process is illustrated as process 224 in the process flow 200 as shown in FIG. 7. Contact plug 71 is also formed to connect to, and land on, source/drain region 50U. There may be source/drain silicide regions (not shown) formed between and contacting deep contact plug 70 and the respective source/drain region 50U, and between and contacting contact plug 71 and the respective source/drain region 50U.

In accordance with some embodiments, the formation of deep contact plug 70 may include etching ILD 54U and CESL 52U (if having a horizontal portion), and etching-through upper source/drain regions 50U to form a trench. Upper source/drain regions 50U may have portions remaining on the opposite sides of the respective opening, which remaining portions are the source/drain regions of the corresponding upper transistor 10U. Bond layers 68U and 68L are also etched-through to exposed metal line 66.

Next, deep contact plug 70 is formed in the respective trench. Deep contact plug 70 may be formed of a conductive material, which may be a metallic material such as tungsten, cobalt, copper, Ti, TiN, Ta, TaN, or the like, combinations thereof, and/or multi-layers thereof. Although not illustrated, source/drain silicide layers may be formed on the exposed portions of source/drain regions 50U before the formation of deep contact plug 70.

Over deep contact plug 70, an interconnect structure is formed, as shown in FIGS. 1I and 1J. As shown in FIG. 1I, dielectric layers 72 and 74 are formed. Another etch stop layer (not shown) may (or may not) be formed between dielectric layers 72 and gate stacks 60U. In accordance with some embodiments, dielectric layer 72 comprises a low-k dielectric material, which may be a silicon-and-carbon containing dielectric material. Dielectric layer 74 may (or may not) act as an etch stop layer, and may be formed of or comprise AlN, AlO, SiOC, and/or the like, combinations thereof, and/or multi-layers thereof. Via 76 is formed in dielectric layer 72, and may (or may not) penetrate through dielectric layer 74.

FIG. 1J illustrates the formation of dielectric layer 78 and metal lines 80. Dielectric layer 78 may also be formed of a low-k dielectric material or a non-low-k dielectric material such as silicon oxide, silicon nitride, silicon carbide, or the like, or combinations thereof. Metal lines 80 may be formed through a damascene process, and may include copper, tungsten, cobalt, nickel, or the like. Each of metal lines 80 may also comprise a diffusion barrier. It is appreciated that although one metal layer is illustrated, the illustrate metal layer and the vias 76 represent a plurality of metal layers and the vias, which collectively form the front-side interconnect structure of wafer 102. FIG. 1J further illustrates the formation of bond layer 82, which may be formed of a material selected from the same group of candidate materials of bond layers 68L and 68U, which material may be a silicon-containing dielectric material.

FIG. 1K illustrates the bonding of carrier 88 to bond layer 82. The respective process is illustrated as process 226 in the process flow 200 as shown in FIG. 7. In accordance with some embodiments, carrier 88 includes semiconductor substrate 86, which may be a silicon substrate in accordance with some embodiments. Bond layer 84 is formed on semiconductor substrate 86. Bond layer 84 may be formed through a deposition process or a thermal oxidation process, and may be formed of a material that is selected from the same group of candidate materials of bond layers 68L and 68U. The bonding of bond layer 84 to bond layer 82 may be through fusion bonding in accordance with some embodiments.

Next, the composite wafer 104, which now includes lower wafer 102, upper wafer 104, and carrier 88 is flipped upside down, and the resulting structure is shown in FIG. 1L. The respective process is also illustrated as process 226 in the process flow 200 as shown in FIG. 7.

Substrate 20 is then removed, for example, in a smart cut process (to remove a majority portion of substrate 20), a CMP process, a mechanical grinding process, and/or an anisotropic etching process. Lower transistor 10L is thus exposed. The respective process is illustrated as process 228 in the process flow 200 as shown in FIG. 7. The resulting structure is shown in FIG. 1M.

FIG. 1M further illustrates the formation of deep contact plug 90. The respective process is also illustrated as process 230 in the process flow 200 as shown in FIG. 7. In accordance with some embodiments, the formation process includes etching-through source/drain region 50L, CESL 52L (if having the horizontal portion), and ILD 54L (FIG. 1L), and filling a conductive material(s) in the resulting opening to form deep contact plug 90. In the etching of ILD 54L, the etch process may be stopped on etch stop layer 62, followed by etching-through etch stop layer 62 in another etching process, which uses an etchant different from the etchant for etching ILD 54L.

In accordance with some embodiments, the source/drain regions 50L (FIG. 1L) may have portions remaining on the opposite sides of deep contact plug 90. The corresponding structure is essentially the same as source/drain region 50U, which has some portions remaining on the opposing sides of deep contact plug 70. In accordance with these embodiments, source/drain silicide regions (not shown) may be formed on the remaining portions of source/drain regions 50L, and physically separate (but electrically interconnect) the remaining portions of source/drain regions 50L from the deep contact plug 90. Accordingly, metal line 66 (the inter-metal) may electrically connect source/drain regions 50L to source/drain regions 50U.

In accordance with alternative embodiments, deep contact plug 90 has its edge contacting the sidewalls of inner spacers 48 and semiconductor nanostructures 26L. There may also be a dielectric liner (not shown) formed encircling contact plug 90 and electrically insulate contact plug 90 from semiconductor nanostructures 26L in accordance with these embodiments.

After the formation of deep contact plug 90, dielectric layers 93 are formed. Dielectric layers 93 may include etch stop layers and low-k dielectric layers in accordance with some embodiments. Contact plug 91 is also formed in dielectric layers 93, and is over and electrically connected to one of source/drain regions 50L. A silicide layer (not shown), may be formed underlying contact plug 91 and over source/drain regions 50L.

Over deep contact plug 90 and contact plug 91, an interconnect structure is formed, as shown in FIGS. 1M and 1N. As shown in FIG. 1M, dielectric layers 92 and 94 are formed. Another etch stop layer (not shown) may also be formed between dielectric layers 92 and 93. In accordance with some embodiments, dielectric layer 92 comprises a low-k dielectric material, which may be a silicon-and-carbon containing dielectric material. Dielectric layer 94 may (or may not) act as an etch stop layer, and may be formed of or comprise AlN, AlO, SiOC, and/or the like, combinations thereof, and/or multi-layers thereof. Vias 96 are formed in dielectric layer 92, and may (or may not) penetrate through dielectric layer 94.

FIG. 1N illustrates the formation of dielectric layer 98 and metal lines 110. Dielectric layer 98 may also be formed of a low-k dielectric material. Metal lines 110 may be formed through a damascene process, and may include copper, tungsten, nickel, or the like. Each of metal lines 110 may also comprise a diffusion barrier. It is appreciated that although one metal layer is illustrated, the illustrated metal layer represents a plurality of metal layers and the connecting vias, which collectively form the backside interconnect structure of wafer 2.

In subsequent processes, more layers/features may be formed, and the resulting composite wafer 104 may be sawed into dies. In the resulting dies obtained from the singulated composite wafer 104 as shown in 1N, the lower transistor 10L is illustrated over upper transistor 10U. Metal line 66 connects to the source/drain region 50U in transistor 10U, and may form a part of a local interconnect structure that connects source/drain region 50U to the source/drain region 50L (if remaining).

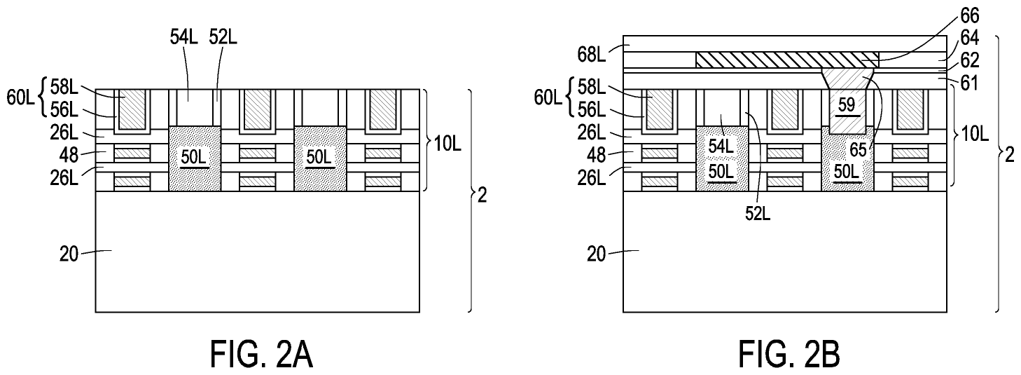

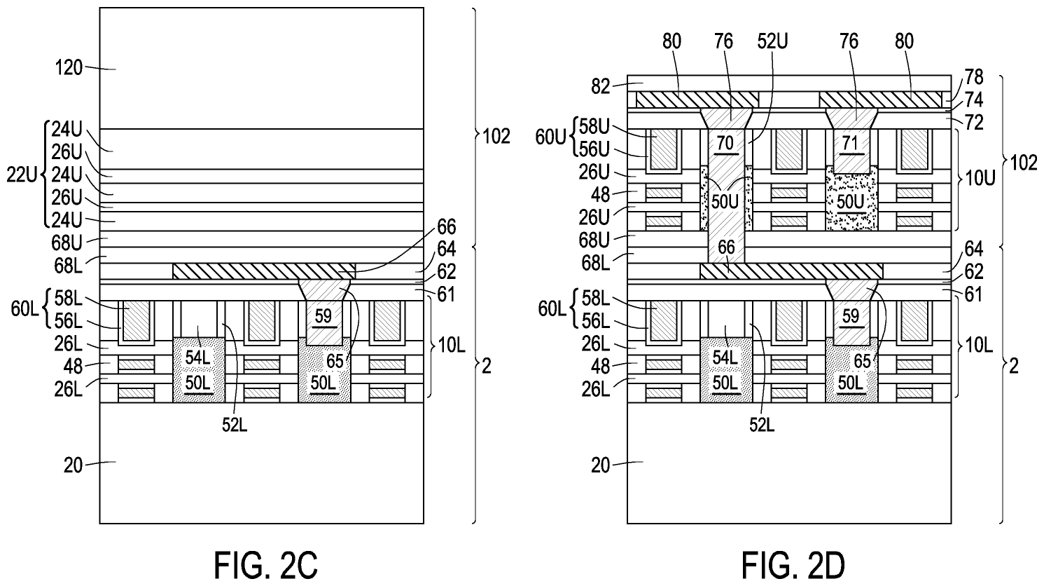

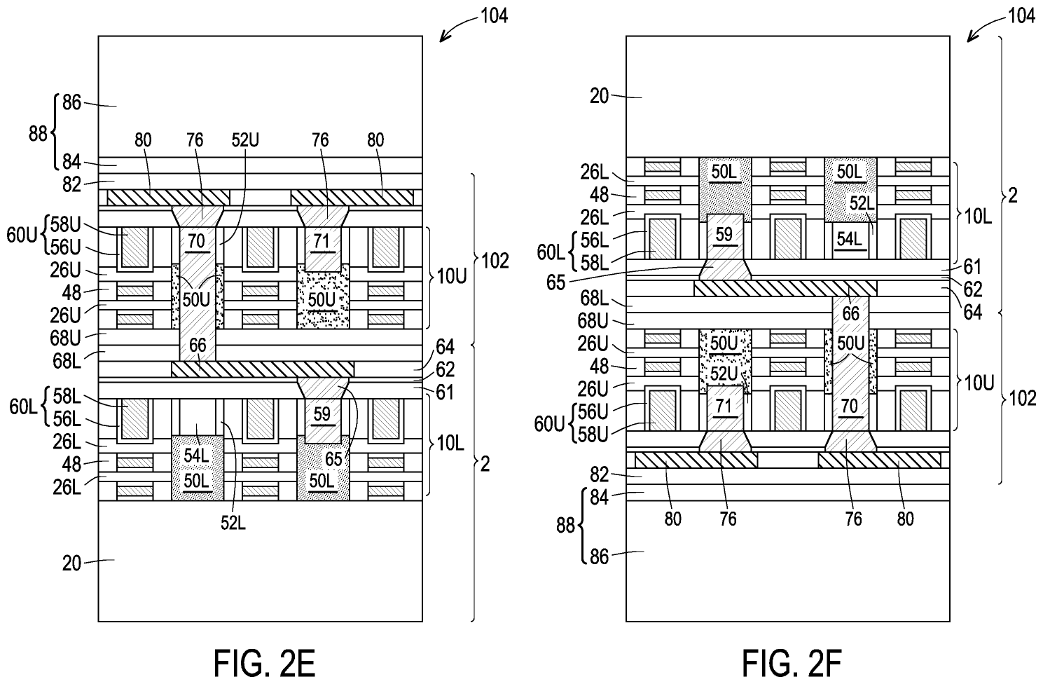

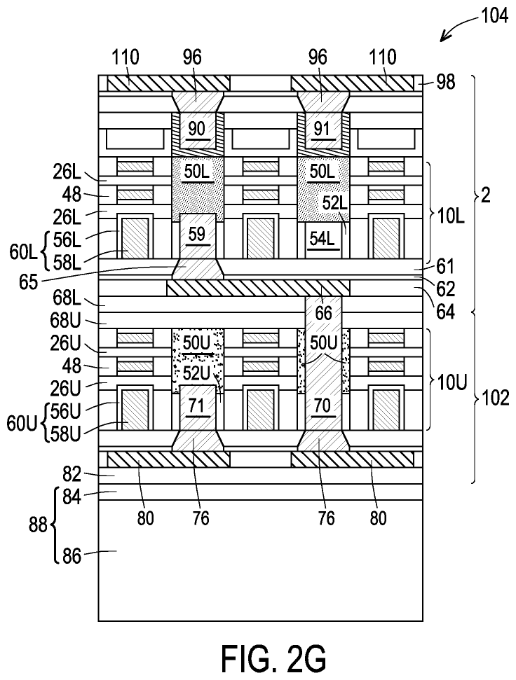

FIGS. 2A-2G illustrate the cross-sectional views of intermediate stages in the formation of CFETs and local interconnects in accordance with alternative embodiments of the present disclosure. The corresponding bonding process is also referred to as a face-to-back process since the front side (the face) of the bottom transistors (and the bottom die/wafer) is bonded to the backside of the upper transistors (and the upper die/wafer).

Unless specified otherwise, the materials, the structures, and the formation processes of the components in these embodiments (and the subsequently discussed embodiments) are essentially the same as the like components denoted by like reference numerals in the preceding embodiments. The details regarding the materials, the structures, and the formation processes provided in any of the embodiments throughout the description may be applied to any other embodiment whenever applicable. Also, the materials, the structures, and the formation processes in FIGS. 2A-2G and the subsequent processes may be realized from the discussion of the discussed embodiments.

The initial processes of these embodiments are essentially the same as shown in FIGS. 1A through 1E. FIG. 2A illustrates a structure that is the same as the structure shown in FIG. 1E, in which transistor 10L is formed. In accordance with some embodiments, transistor 10L includes semiconductor nanostructures 26L forming the channels, source/drain regions 50L, and gate stacks 60L wrapping around the semiconductor nanostructures 26L.

Referring to FIG. 2B, dielectric layers 62 and 64, metal line 66 (the inter-metal), and bond layer 68L are formed. The structures, materials and the formation processes of dielectric layers 62 and 64, metal line 66, and bond layer 68L are essentially the same as what have been discussed referring to FIG. 1F, and are not repeated herein.

Different from the structure as shown in FIG. 1F, source/drain contact plug 59 is formed during an early stage (rather than in the process shown in FIG. 1M) to extend into CESL 52L and ILD 54L, and is electrically connected to source/drain region 50L. Although not shown, a source/drain silicide region may be formed between source/drain region 50L and source/drain contact plug 59. In addition, dielectric layer 61 is formed, and via 65 is formed in dielectric layer 61 to electrically connect source/drain contact plug 59 and source/drain region 50L to metal line 66. Dielectric layer 61 may be formed of silicon oxide, silicon nitride, PSG, BSG, BPSG, USG, a low-k dielectric material, or the like. As a comparison, in the structure shown in FIG. 1F, metal line 66 is electrically decoupled from source/drain region 50L at this stage.

FIG. 2C illustrates the bonding of upper wafer 102 to lower wafer 2. Upper wafer 102 may be essentially the same as discussed in preceding embodiments. Upper wafer 102 may include semiconductor substrate 120, and alternating semiconductor layers 26U and dummy semiconductor layers 24U. The bonding may be achieved by bonding bond layer 68U in the upper wafer 102 to the bond layer 68L in lower wafer 2.

Next, as shown in FIG. 2D, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Furthermore, deep contact plug 70 is formed to connect to metal line 66 and source/drain region 50U. Contact plug 71 is also formed to land on and electrically connect to another source/drain region 50U. Vias 76 and metal lines 80 are also formed to electrically connect to deep contact plug 70 and contact plug 71. Vias 76 and metal lines 80 are formed in dielectric layers 72, 74, and 78. Bond layer 82 is also formed, and may be planarized.

FIG. 2E illustrates the bonding of carrier 88 to bond layer 82 to form composite wafer 104. The resulting composite wafer 104 is then flipped upside down, and the resulting structure is shown in FIG. 2F. Substrate 20 is then removed, for example, in a smart cut process (to remove a majority portion of substrate 20), a CMP process, a mechanical grinding process, and/or an anisotropic etching process. Lower transistor 10L is thus exposed. The resulting structure is shown as a part of the structure in FIG. 2G.

FIG. 2G further illustrates the formation of additional features including source/drain contact plugs 91, and a backside interconnect structure on the backside of wafer 2. Although not illustrated, there may be metal silicide regions formed between source/drain contact plugs 91 and source/drain regions 50L. The backside interconnect structure includes vias 96 and metal lines 110, and the corresponding dielectric layers including dielectric layer 98. While the backside interconnect structure has one metal layer and the underlying vias illustrated in an example, the backside interconnect structure may include a plurality of metal layers and the connecting vias.

In subsequent processes, more layers/features may be formed, and the resulting composite wafer 104 may be sawed into dies. In the resulting dies obtained from the singulated composite wafer 104, source/drain contact plugs 91 are electrically connected to source/drain regions 50U through source/drain regions 50L, metal line 66, and deep contact plug 70. Differing from the embodiments in FIG. 1N, in which both of the source/drain regions 50L and 50U are penetrated-through in order to provide the electrical paths through them, one of source/drain regions 50L is used to provide through-interconnection. Metal line 66, via 65, and a part of deep contact plug 70 thus collectively form parts of the local interconnect for interconnecting.

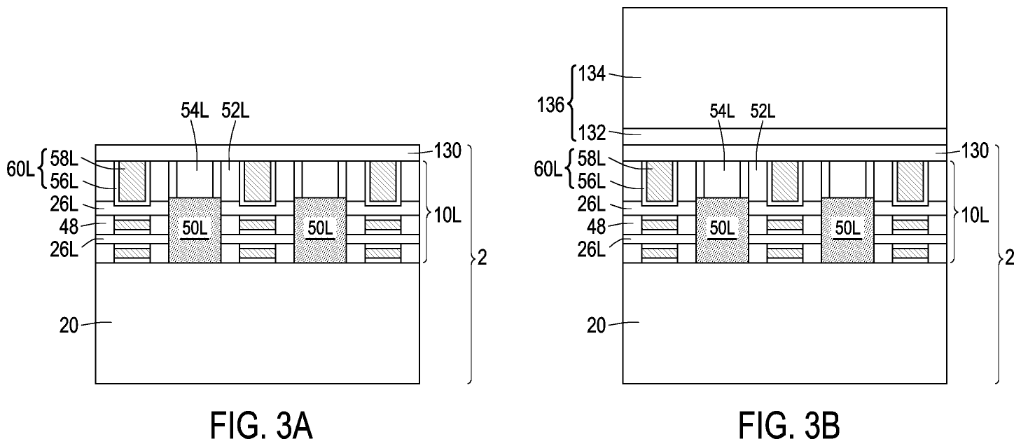

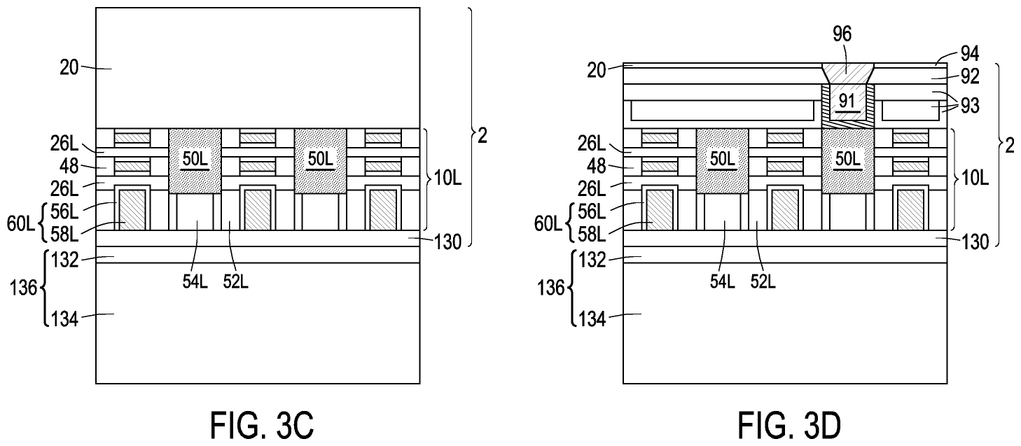

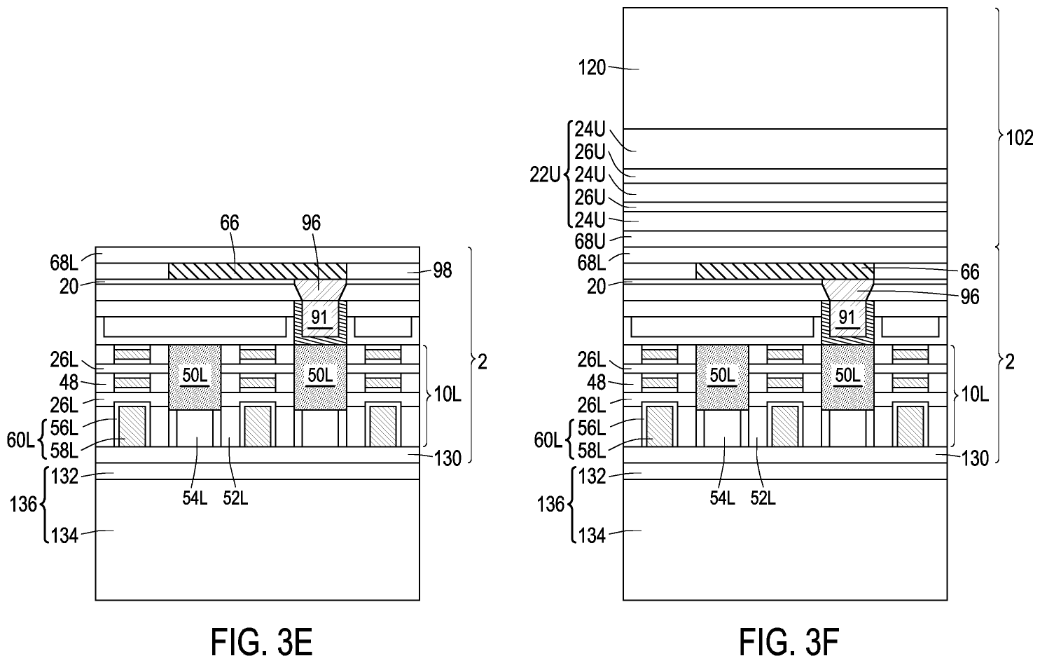

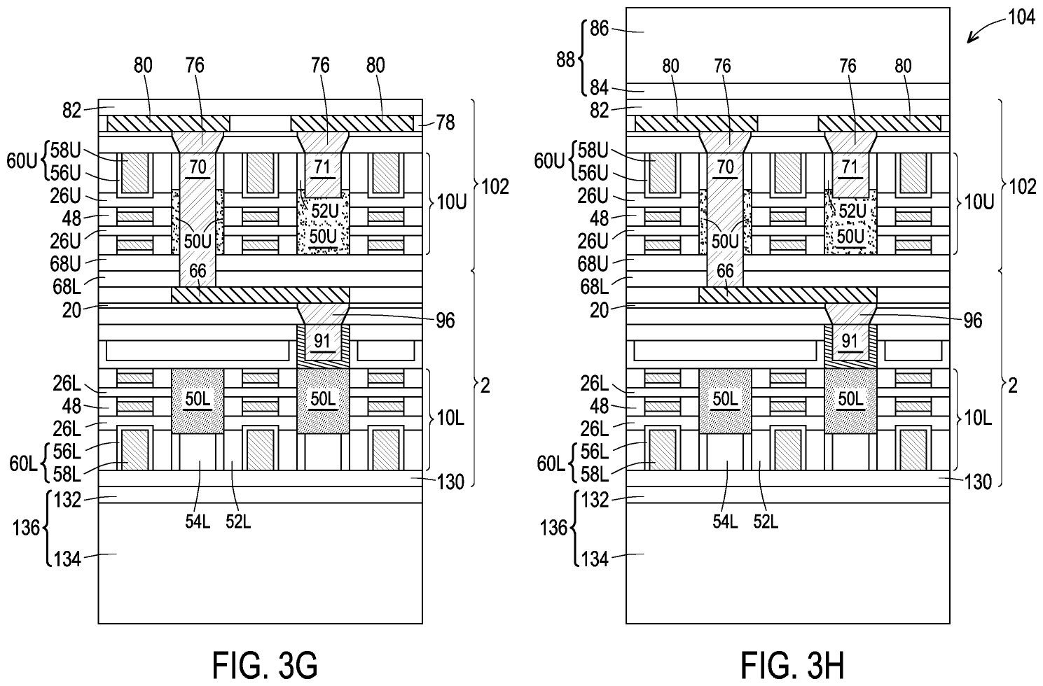

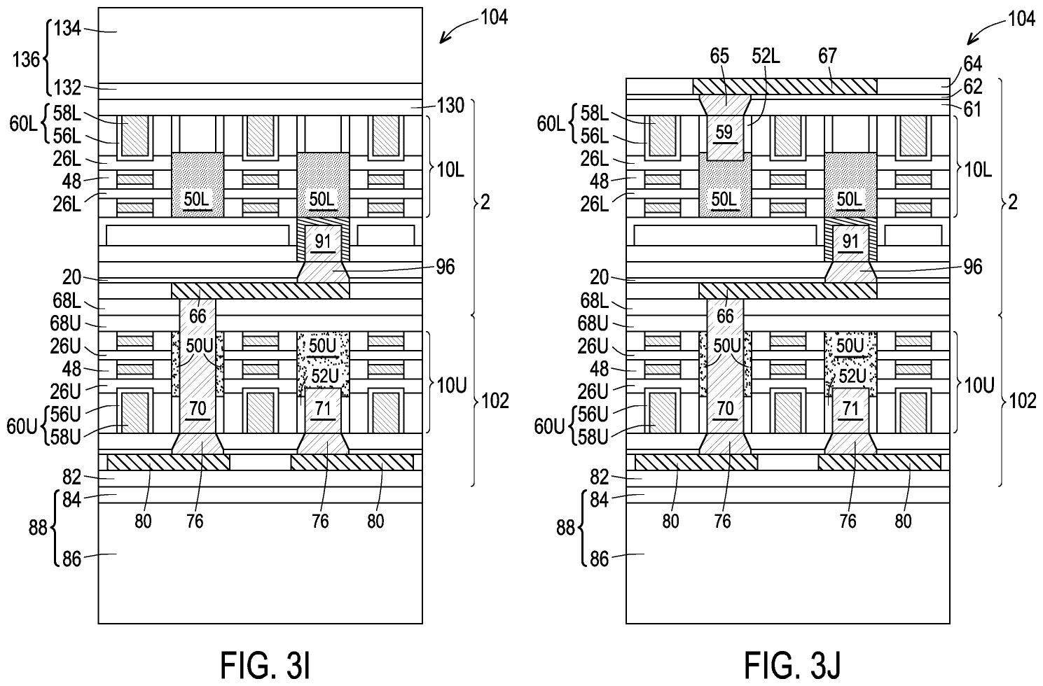

FIGS. 3A-3J illustrate the cross-sectional views of intermediate stages in the formation of CFETs and local interconnects in accordance with alternative embodiments of the present disclosure. The corresponding bonding process is also referred to as a back-to-back process since the backside of the bottom transistors (and the bottom die/wafer) is bonded to the backside of the upper transistors (and the upper die/wafer).

These processes are essentially the same as the processes shown in preceding figures, except that before bonding an upper wafer to a lower wafer, a carrier is attached to the front side of the lower wafer, and the original substrate of the lower wafer is removed.

The initial processes of these embodiments are essentially the same as shown in FIGS. 1A through 1E. FIG. 3A illustrates a structure that is the same as the structure shown in FIG. 1E. In accordance with some embodiments, transistor 10L includes semiconductor nanostructures 26L forming the channels, source/drain regions 50L, and gate stacks 60L wrapping around the semiconductor nanostructures 26L.

FIG. 3A further illustrates the formation of bond layer 130 as a part of the lower wafer 2. Bond layer 130 is bonded to the front side of wafer 2, and may be in contact with gate stacks 60L. The bond layer 130 may be a silicon-containing dielectric layer, which may include SiO, SiC, SiN, SiCN, SiOC, SiOCN, SiON, or the like. In accordance with some embodiments, bond layer 130 is planarized to have a planar top surface.

FIG. 3B illustrates the bonding of carrier 136 to wafer 2 through bonding to bond layer 130. In accordance with some embodiments, carrier 136 includes semiconductor substrate 134, which may be a silicon substrate. Bond layer 132 is formed on semiconductor substrate 134 in accordance with these embodiments. Bond layer 132 may be formed through a deposition process or a thermal oxidation process, and may be formed of a material that is selected from the same group of candidate materials of bond layer 130. The bonding of bond layer 132 to bond layer 130 may be through fusion bonding in accordance with some embodiments.

In accordance with alternative embodiments, carrier 136 includes a transparent substrate (also denoted using reference numeral 134) such as a glass substrate, which is attached to lower wafer 2 through an adhesive such as a light-to-heat-Conversion (LTHC) material (also denoted using reference numeral 132), which is configured to be decomposed under the heat of light (such as a laser beam). The structure including lower wafer 2 and carrier 136 is then flipped upside down, and the resulting structure is shown in FIG. 3C.

Substrate 20 is then removed, for example, in a smart cut process (to remove a majority portion of substrate 20), a CMP process, a mechanical grinding process, and/or an anisotropic etching process. Lower transistor 10L is thus exposed. The resulting structure is shown as being a lower part of the structure in FIG. 3D.

FIG. 3D further illustrates the formation of contact plug 91, via 96, and a plurality of dielectric layers 93, 92, and 94. Another etch stop layer (not shown) may also be formed between dielectric layers 92 and 93. In accordance with some embodiments, dielectric layer 92 comprises a low-k dielectric material, which may be a silicon-and-carbon containing dielectric material. Dielectric layer 94 may (or may not) act as an etch stop layer, and may be formed of or comprise AlN, AlO, SiOC, and/or the like, combinations thereof, and/or multi-layers thereof. Via 96 is formed in dielectric layer 92, and may (or may not) penetrate through dielectric layer 94.

FIG. 3E illustrates the formation of dielectric layer 98 and metal line 66, which is electrically connected to source/drain region 50L through via 96 and contact plug 91. Bond layer 68L is then formed, which may be formed of a silicon-containing dielectric material such as SiO, SiN, SiC, SiCN, SiOCN, or the like.

Next, referring to FIG. 3F, upper wafer 102 is bonded to lower wafer 2. Upper wafer 102 may be essentially the same as discussed in preceding embodiments. Upper wafer 102 may include semiconductor substrate 120, and alternating semiconductor layers 26U and dummy semiconductor layers 24U. The bonding may be achieved by bonding bond layer 68U to bond layer 68L.

Next, as shown in FIG. 3G, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Further referring to FIG. 3G, deep contact plug 70 and contact plug 71 are formed to connect to metal line 66 and source/drain region 50U, respectively. Vias 76 and metal lines 80 are also formed, which are in dielectric layers 72, 74, and 78. Bond layer 82 is also formed, and may be planarized. In accordance with some embodiments, bond layer 82 is formed of or comprises a silicon-containing dielectric material such as SiO, SiN, SiN, SION, SiCN, SiOCN, or the like, combinations thereof, and/or multi-layers thereof. In accordance with alternative embodiments, instead of forming a bond layer, a buffer layer (also referred to as bond layer 82) may be formed, and may comprise a polymer such as polyimide or Polybenzoxazole (PBO).

FIG. 3H illustrates the bonding of carrier 88 to bond layer 82, hence forming composite wafer 104. The resulting composite wafer 104 is then flipped upside down, and the resulting structure is shown in FIG. 3I. Carrier 136 is then removed, for example, in a CMP process, a mechanical grinding process, or an etching process when carrier 136 comprises a semiconductor substrate. When carrier 136 is a glass carrier adhered to the underlying structure through an LTHC 132, a laser beam may be used to decompose LTHC 132, thus de-bonding carrier 136.

FIG. 3J illustrates the formation of additional features including source/drain contact plugs 91, and an interconnect structure including via 65 and metal line 67, and the corresponding dielectric layers. In subsequent processes, more layers/features may be formed, and the resulting composite wafer 104 may be sawed into dies. In the resulting dies obtained from the singulated composite wafer 104, metal line 66 acts as a part of the local interconnect for interconnecting source/drain regions 50L and 50U.

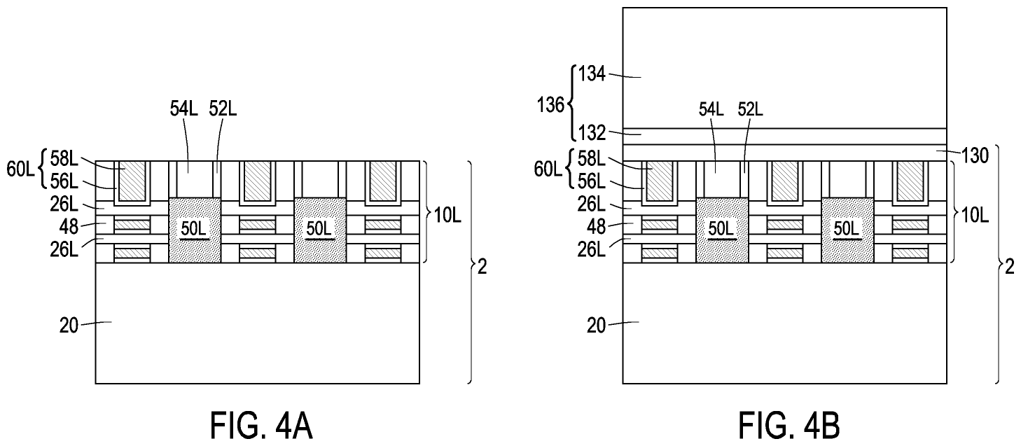

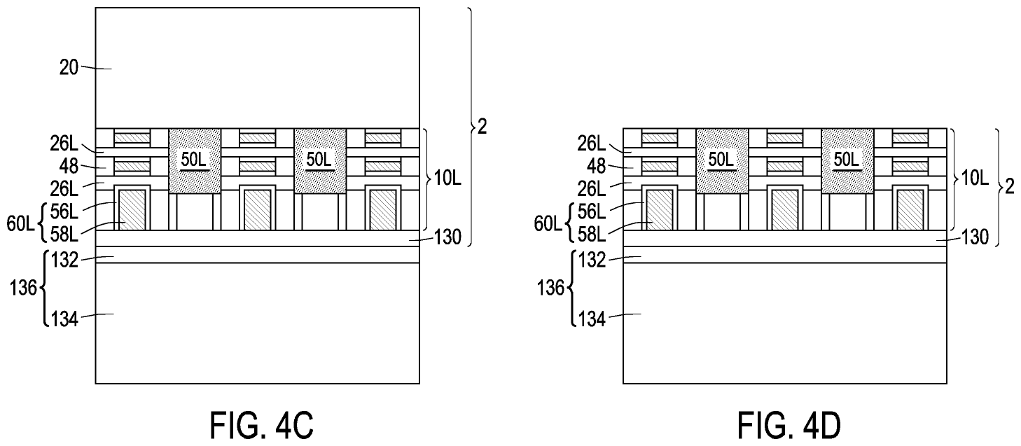

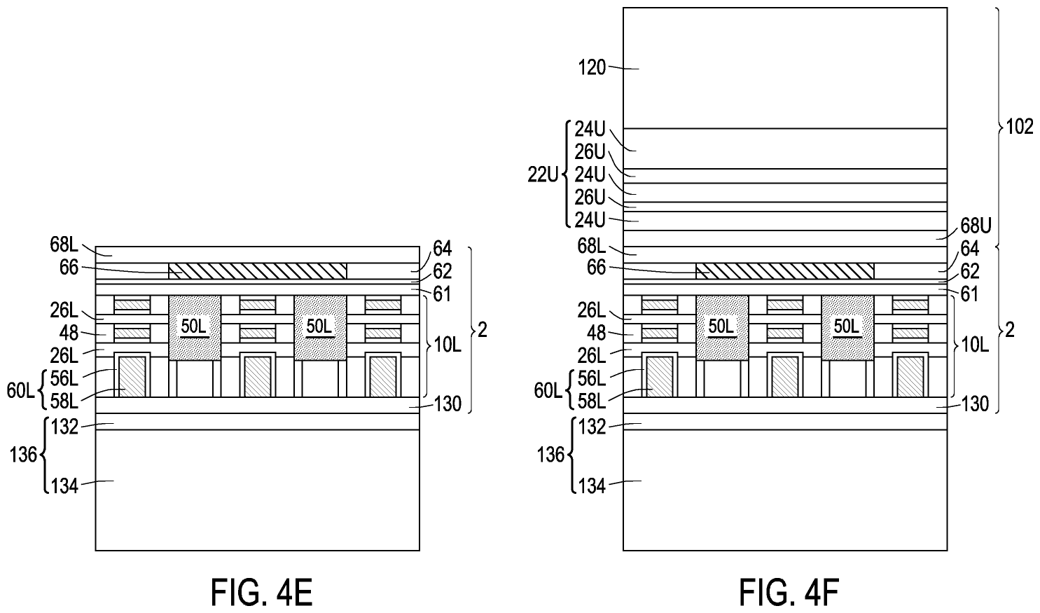

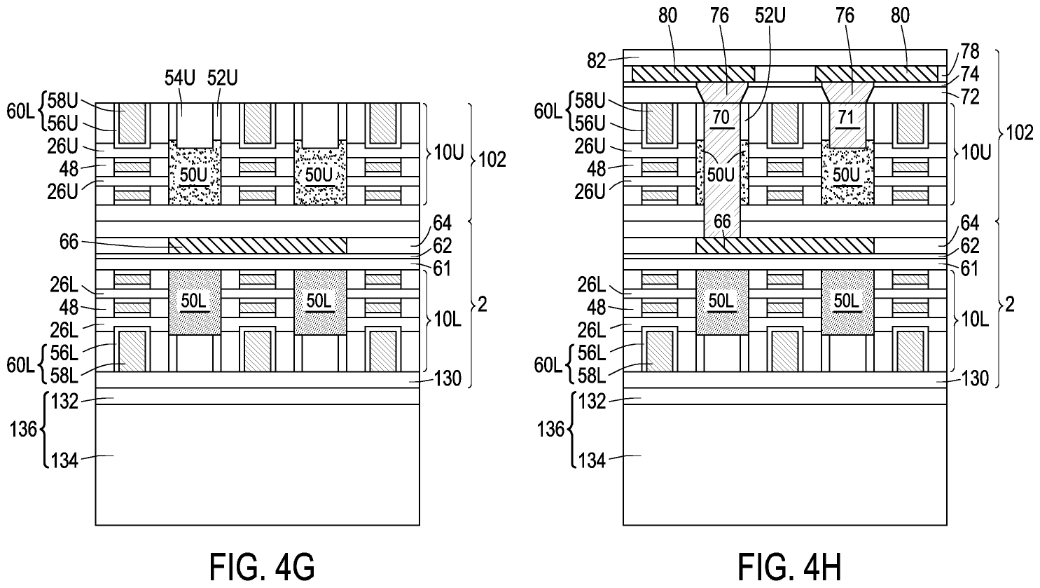

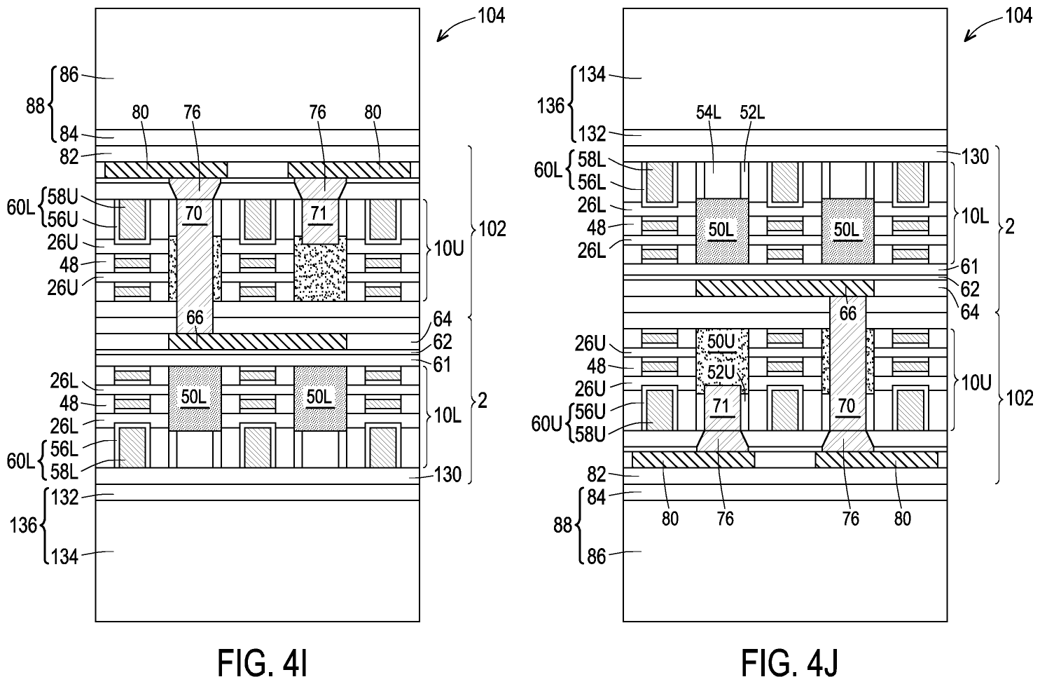

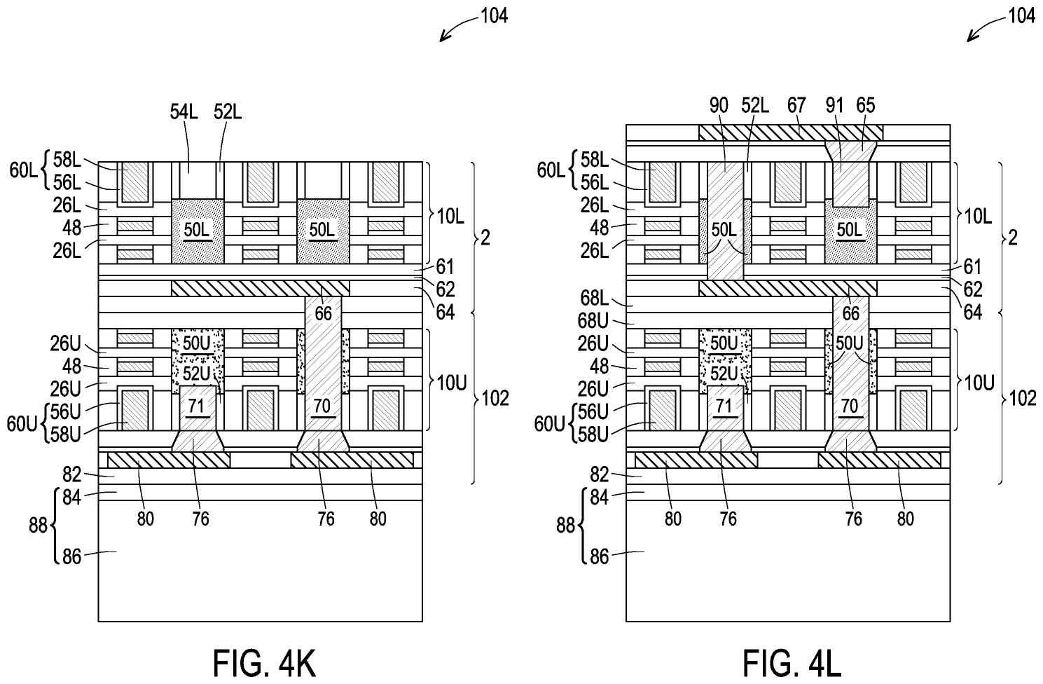

FIGS. 4A-4L illustrate the cross-sectional views of intermediate stages in the formation of CFETs and local interconnects in accordance with alternative embodiments of the present disclosure. The corresponding bonding process is also referred to as a back-to-back process since the backside of the bottom transistors (and the bottom die/wafer) is bonded to the backside of the upper transistors (and the upper die/wafer).

These processes are essentially the same as the processes shown in Figures u, except that the connection from source/drain regions 50L to metal line 66 is formed after the formation of transistor 10U (and in FIG. 4L), rather than in a step (FIG. 3D) that is performed before the bonding of upper wafer to the bottom wafer.

The processes shown in FIGS. 4A, 4B, and 4C are the same as the processes shown in FIGS. 3A, 3B, and 3C, respectively, in which transistor 10L is formed. In accordance with some embodiments, transistor 10L includes semiconductor nanostructures 26L forming the channels, source/drain regions 50L, and gate stacks 60L wrapping around the semiconductor nanostructures 26L. As also shown in FIG. 4C, carrier 136 is attached, with substrate 134 being a semiconductor substrate (such as a silicon substrate) or a glass carrier, and layer 132 being a bond layer or an LTHC.

The processes shown in FIGS. 4D and 4E are similar to the processes shown in FIGS. 3D and 3E, in which dielectric layers 61 and 64 are formed, and metal line 66 is formed in dielectric layer 64. Etch stop layer 61 may also be formed to stop the etching for forming metal line 66. At this stage, metal line 66 (the inter-metal) is electrically decoupled from source/drain regions 50L. Rather, the connection of source/drain regions 50L to metal line 66 will be formed after upper transistors are formed.

FIG. 4E further illustrates the formation of bond layer 68L as a part of the lower wafer 2. bond layer 68L is formed on the front side of wafer 2, and may be in contact with gate stacks 60L. The material of bond layer 68L may be a silicon-containing dielectric material, which may include SiO, SiC, SiN, SiCN, SiOC, SiOCN, SiON, or the like. In accordance with some embodiments, bond layer 68L is planarized to have a planar top surface.

Next, referring to FIG. 4F, upper wafer 102 is bonded to lower wafer 2. Upper wafer 102 is essentially the same as discussed in preceding embodiments. Upper wafer 102 may include semiconductor substrate 120, and alternating semiconductor layers 26U and dummy semiconductor layers 24U. The bonding may be achieved by bonding bond layer 68U to bond layer 68L.

Next, as shown in FIG. 4G, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Referring to FIG. 4H, deep contact plug 70 and contact plug 71 are formed to connect to metal line 66 (and one of source/drain regions 50U) and source/drain region 50U, respectively. Vias 76 and metal lines 80 are also formed, which are in dielectric layers 72, 74, and 78. Bond layer 82 is also formed, and may be planarized.

FIG. 4I illustrates the bonding of carrier 88 to bond layer 82. Carrier 88 may include semiconductor substrate 86 (such as a silicon substrate), and bond layer 84 bonding to bond layer 82, thus forming composite wafer 104. The resulting composite wafer 104 is then flipped upside down, and the resulting structure is shown in FIG. 4J.

Carrier 136 is then removed. The resulting structure is shown in FIG. 4K. When carrier 136 is a glass carrier adhered to the underlying structure through an LTHC 132, a laser beam may be used to decompose LTHC 132, thus de-bond carrier 136. Otherwise, when substrate 134 is a semiconductor substrate, substrate 134 may be removed in a smart cut process, a CMP process, a mechanical grinding process, and/or an anisotropic etching process.

FIG. 4L illustrates the formation of deep contact plug 90, which acts as both of the source/drain contact plug and the deep via connecting the metal line 66. Deep contact plug 90 penetrates through the respective source/drain region 50L. Contact plug 91 is also formed to connect to one of source/drain regions 50L. There may be source/drain silicide regions (not shown) formed between contact plug 91 and source/drain region 50L.

The formation of deep contact plug 90 may also include etching ILD 54L, CESL 52L (when comprising the horizontal portion), source/drain region 50L, and dielectric layer 61. The etching is stopped on etch stop layer 62. Another etching process is used to etch-through etch stop layer 62 and to reveal metal line 66. The etching chemical used for etching the etch stop layer 62 may be different from what is used for etching dielectric layer 61. The resulting trench is then filled with conductive materials to form deep contact plug 90. Although not illustrated, source/drain silicide layers may be formed between, and contacting upper source/drain region 50U and deep contact plug 90. Source/drain region 50L is thus electrically connected to source/drain region 50U through metal line 66, which acts as an inter-metal between transistors 10L and 10U.

Over deep contact plug 90 and contact plug 91, an interconnect structure is formed. FIG. 4L illustrates the formation of a plurality of dielectric layers, via 65, and metal line 67. The dielectric layers may also be formed of low-k dielectric materials. Metal lines 67 may be formed through a damascene process, and may include copper, tungsten, nickel, or the like. Metal line 67 may also comprise a diffusion barrier. It is appreciated that although one metal layer is illustrated, the illustrated metal layer represents a plurality of metal layers, which collectively form the front-side interconnect structure of wafer 2.

In subsequent processes, more layers/features may be formed, and the resulting composite wafer 104 may be sawed into dies. In the resulting dies obtained from the singulated composite wafer 104, metal line 66 acts as a part of the local interconnect for interconnecting source/drain regions 50L and 50U.

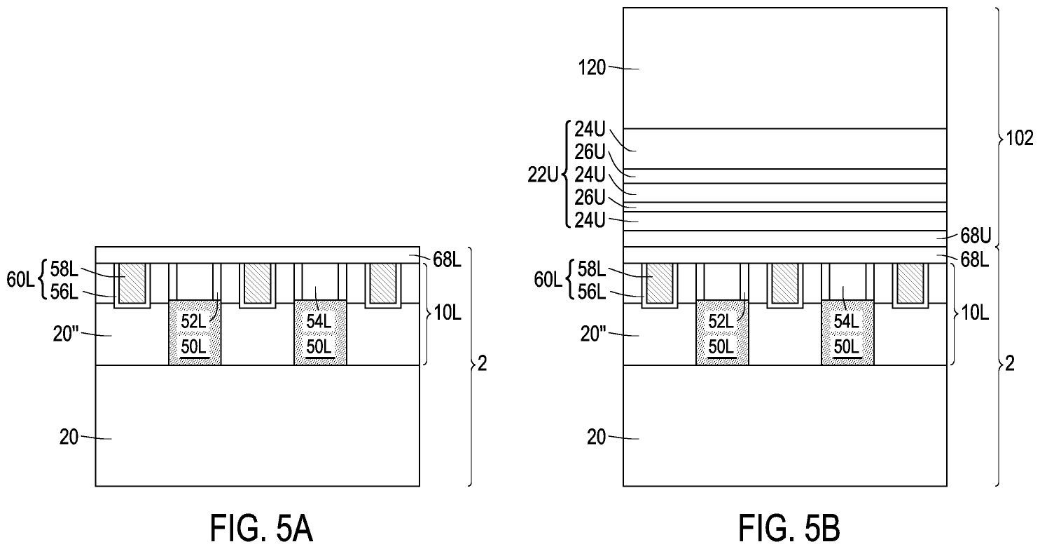

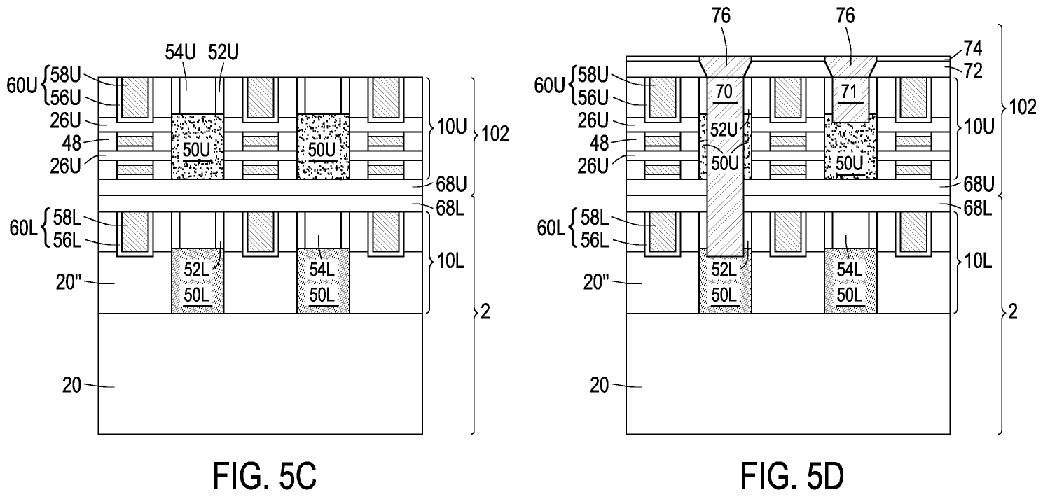

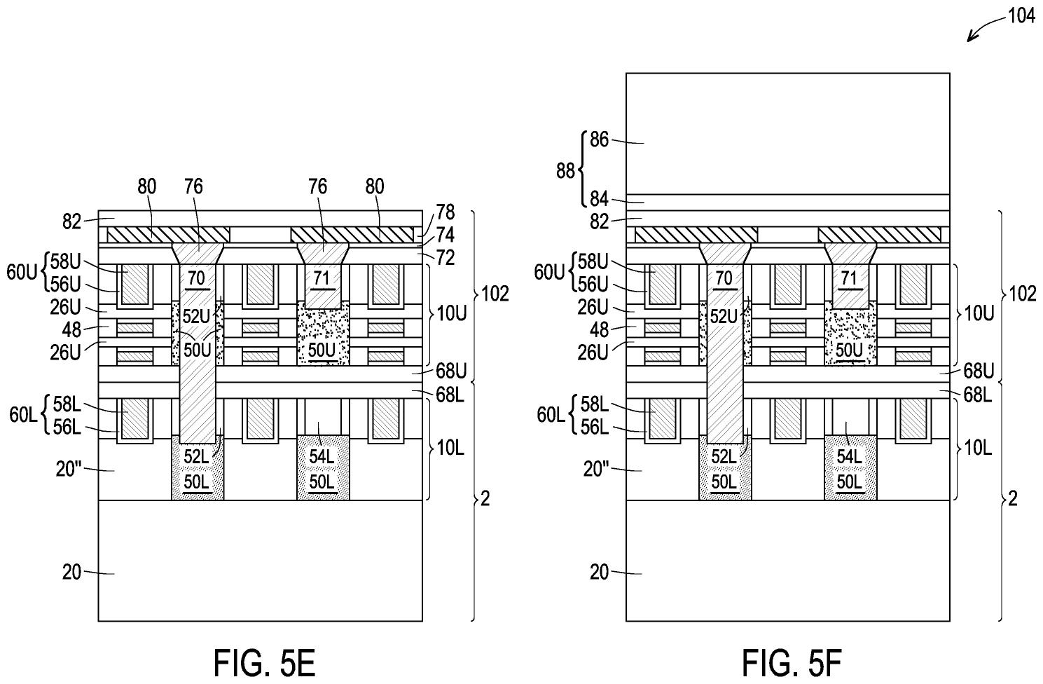

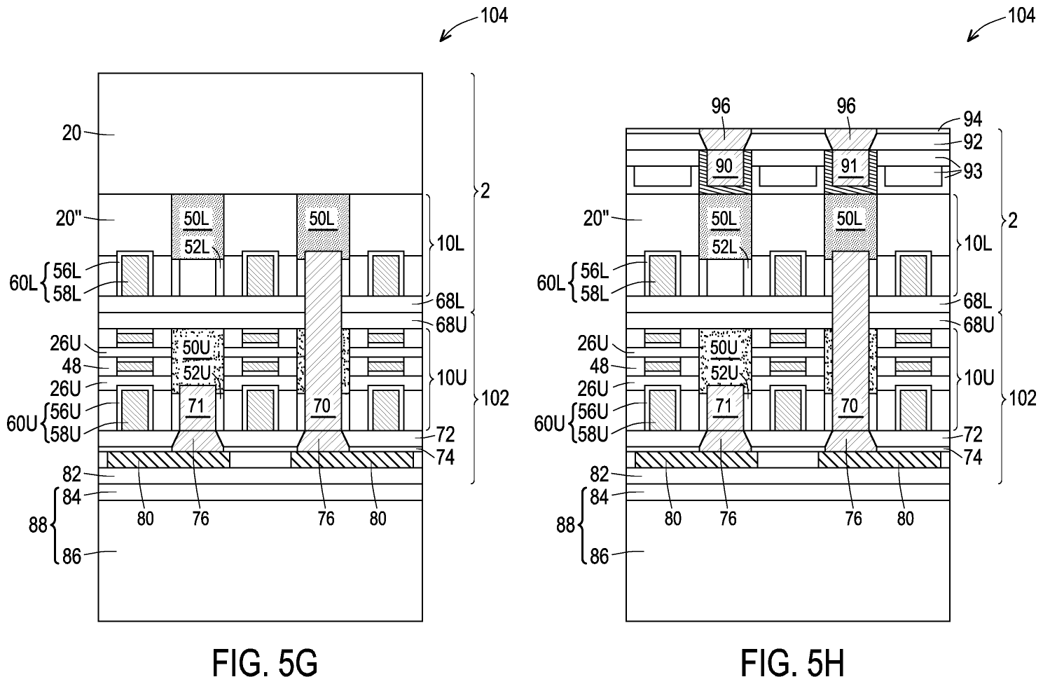

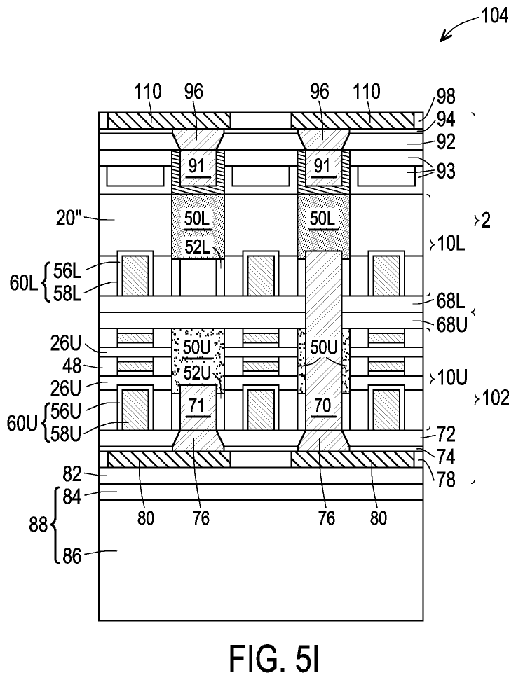

FIGS. 5A-5I illustrate the cross-sectional views of intermediate stages in the formation of CFETs and local interconnects in accordance with alternative embodiments of the present disclosure. The corresponding bonding process is also referred to as a face-to-back process since the front side of the bottom transistors (and the bottom die/wafer) is bonded to the backside of the upper transistors (and the upper die/wafer).

These processes are similar to the processes shown in FIGS. 1A-1N, except that no horizontal metal line is formed between upper transistors and lower transistors for routing electrical signals (and that the lower transistor is illustrated as a FinFET). Alternatively stated, the electrical signals/voltages are routed between the upper transistors and lower transistors vertically, and through deep contact plugs.

FIG. 5A illustrates the formation of transistor 10L in lower wafer 2. In accordance with some embodiments, transistor 10L is a FinFET, which includes source/drain regions 50L, protruding semiconductor fin 20″ that protrudes higher than the bulk portion of substrate 20, and gate electrodes 60 extending on the sidewalls and the top surfaces of protruding semiconductor fin 20″. The protruding semiconductor fin 20″ is further over a bulk semiconductor substrate. In accordance with alternative embodiments, transistors 10L may be a GAA transistor, as shown in FIG. 1E.

Next, as also shown in FIG. 5A, bond layer 68L is formed. Differing from the structure shown in FIG. 1F, in which an inter-metal is formed in lower wafer 2, in the structure shown in FIG. 5A, no horizontal metal line/pad is formed over transistor 10L.

FIG. 5B illustrates the bonding of upper wafer 102 to lower wafer 2. Upper wafer 102 is essentially the same as discussed in preceding embodiments, and the details are not repeated herein. Upper wafer 102 may include semiconductor substrate 120, and alternating semiconductor layers 26U and dummy semiconductor layers 24U. The bonding may be achieved by bonding bond layer 68U to bond layer 68L.

Next, as shown in FIG. 5C, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L. Also, although transistor 10U is illustrated as a GAA transistor in an example, transistor 10U may also be a FinFET in accordance with alternative embodiments.

Next, referring to FIG. 5D, contact plug 71 is formed. Contact plug 71 is electrically connected to one of source/drain regions 50U, and is landed on the top surface of the source/drain region 50U. There may be a silicide region (not shown) between and contacting contact plug 71 and source/drain region 50U.

Deep contact plug 70 is also formed, and penetrates through one of source/drain regions 50U and lands on one of the source/drain regions 50L. Deep contact plug 70 acts as both of the source/drain contact plug and the deep via (the local interconnect) interconnecting source/drain regions 50U and 50L. In accordance with some embodiments, the formation process may include etching ILD 54U (FIG. 5A) and CESL 52U (if having horizontal portions), source/drain regions 50U, bond layers 68U and 68L, ILD 54L, and CESL 52L (if having horizontal portions). The source/drain region 50L is thus exposed to the respective trench. A conductive material(s) is then filled into the resulting trench to form deep contact plug 70. There may be source/drain silicide regions (not shown) formed between deep contact plug 70 and source/drain region 50U, and between deep contact plug 70 and source/drain region 50L.

Referring to FIGS. 5D and 5E, vias 76 and metal lines 80 are also formed, which are in dielectric layers 72, 74, and 78. Bond layer 82 is also formed, and may be planarized.

FIG. 5F illustrates the bonding of carrier 88 to bond layer 82, thus forming composite wafer 104. The resulting composite wafer 104 is then flipped upside down, and the resulting structure is shown in FIG. 5G. Substrate 20 is then removed, for example, in a smart cut process, a CMP process, a mechanical grinding process, and/or an anisotropic etching process. The protruding semiconductor fin 20″ and source/drain regions 50L in the lower transistor 10L are thus exposed.

FIG. 5H illustrates the formation of additional features including source/drain contact plugs 91, and an interconnect structure including via 96 and the corresponding dielectric layers 93, 92, and 94. Although not illustrated, there may be metal silicide regions formed between source/drain contact plugs 91 and source/drain regions 50L. Source/drain contact plugs 91 are thus electrically connected to source/drain regions 50U through source/drain regions 50L and deep contact plug 70. Differing from the embodiments in FIG. 1N, in which both of the source/drain regions 50L and 50U are penetrated-through in order to provide the electrical paths through them, one of source/drain regions 50L is used to provide through-connection.

FIG. 5I illustrates the formation of an interconnect structure including dielectric layers and metal lines, which are represented by dielectric layer 98 and metal lines 110. In subsequent processes, more overlying metal layers and vias may be formed, and the resulting composite wafer 104 may be sawed into dies. In the resulting dies obtained from the singulated composite wafer 104, the deep contact plug 70 acts as a part of the local interconnect for interconnecting source/drain regions 50L and 50U.

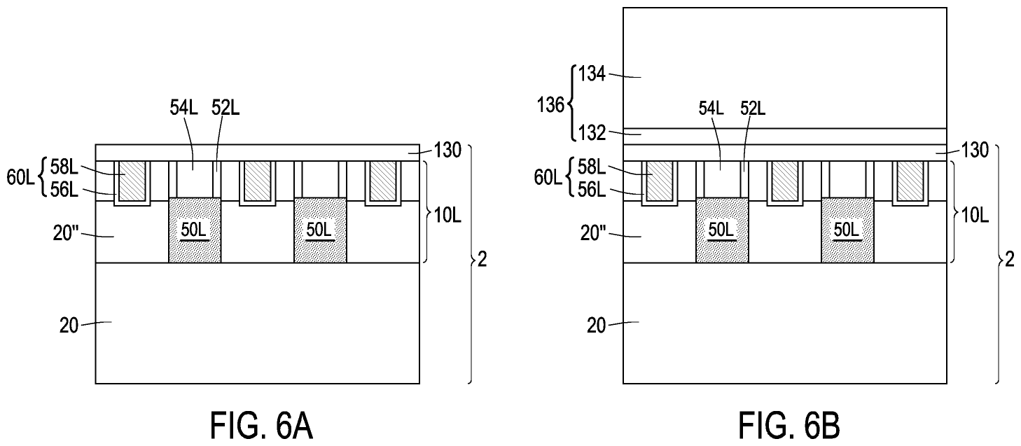

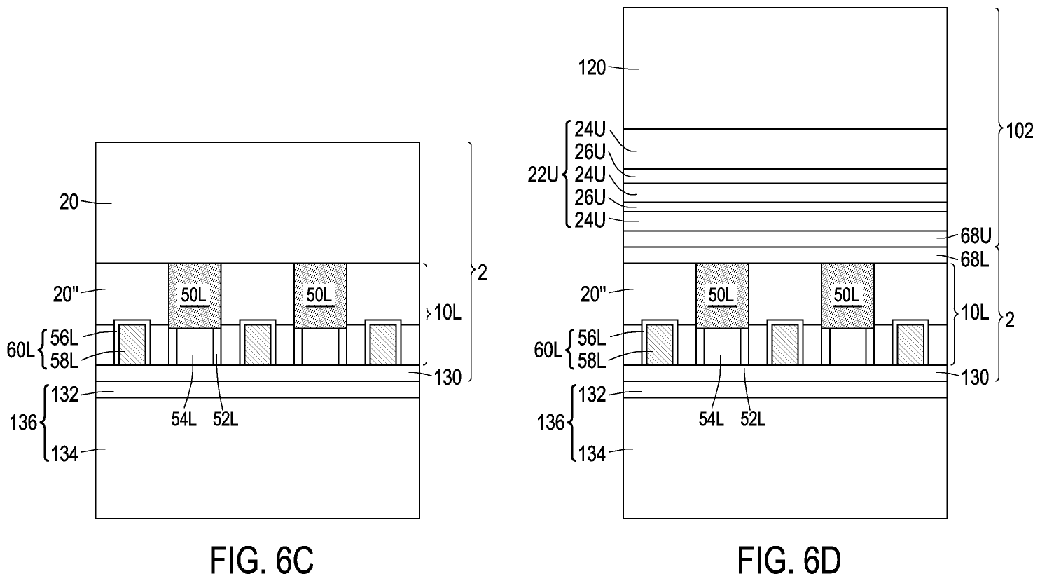

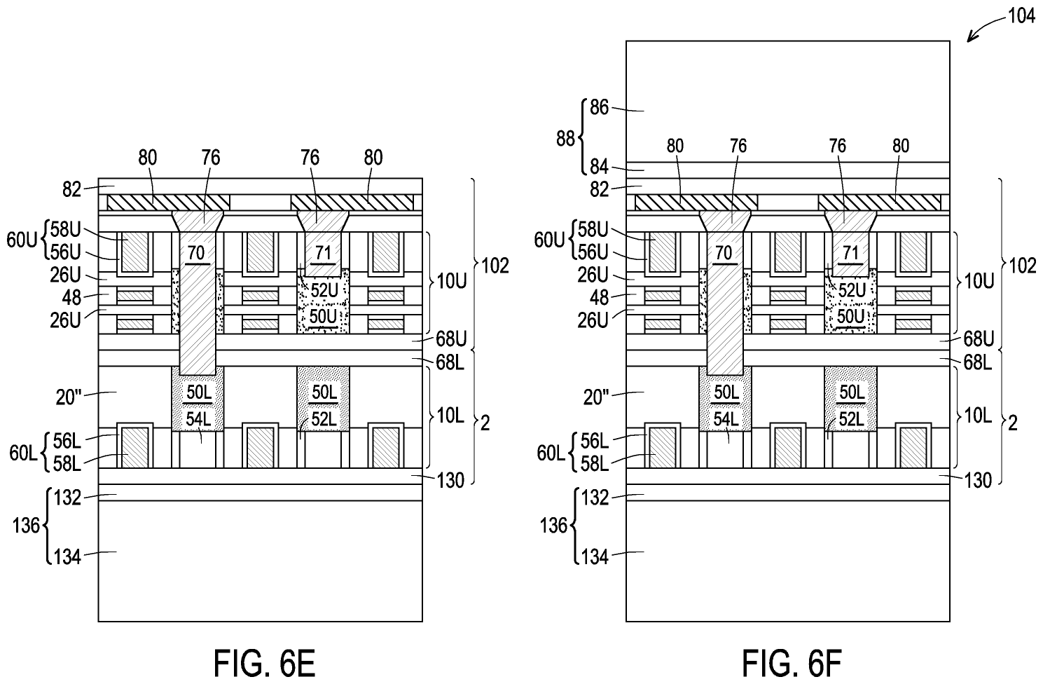

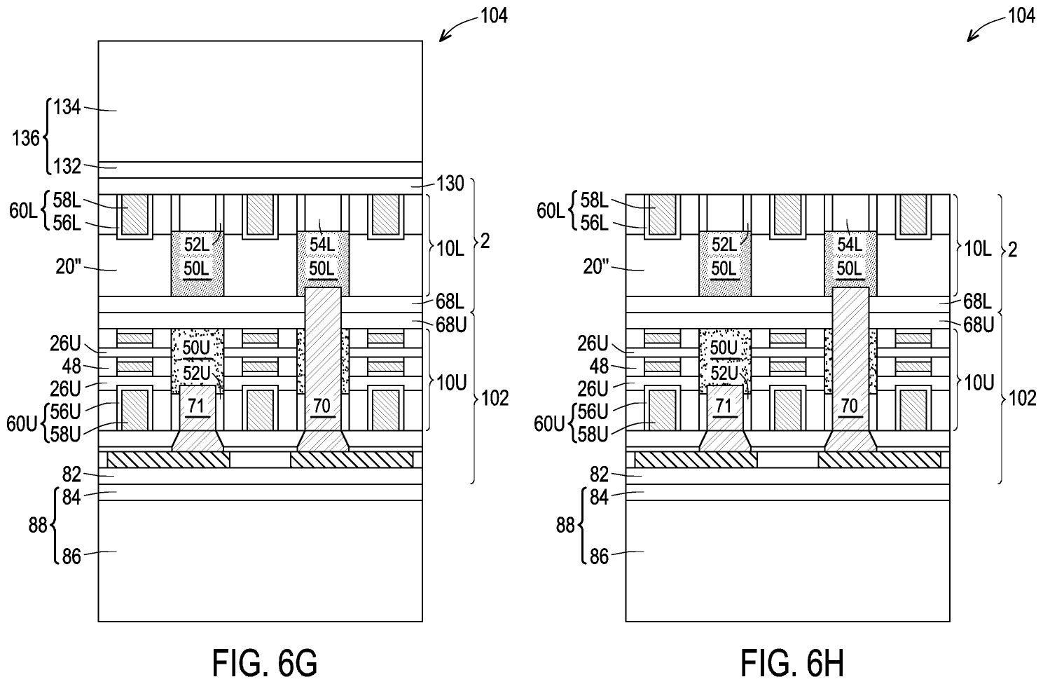

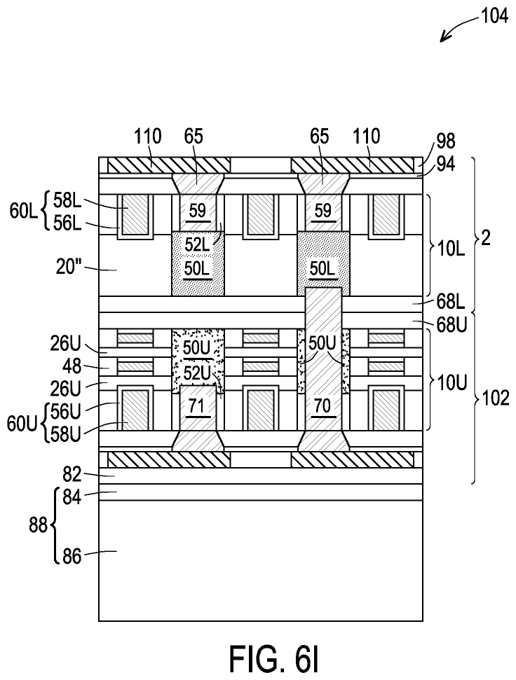

FIGS. 6A-6I illustrate the cross-sectional views of intermediate stages in the formation of CFETs and local interconnects in accordance with alternative embodiments of the present disclosure. The corresponding bonding process is also referred to as a back-to-back process since the backside of the bottom transistors (and the bottom die/wafer) is bonded to the backside of the upper transistors (and the upper die/wafer).

These processes are similar to the processes shown in FIGS. 3A-33I, except that no metal line (inter-metal) is formed between upper transistors and lower transistors. Alternatively stated, no horizontal metal lines are formed between the upper transistors and lower transistors. Rather, the connection of the transistors and lower transistors are through deep contact plugs. Furthermore, in accordance with these embodiments, lower transistor 10L may be a FinFET as shown in FIG. 6A, or may be a GAA transistor.

FIG. 6A illustrates the formation of transistor 10L in lower wafer 2. In accordance with some embodiments, transistor 10L is a FinFET, which includes source/drain regions 50L, protruding semiconductor fin 20″ that protrudes higher than the bulk portion of substrate 20, and gate electrodes 60 extending on the sidewalls and the top surfaces of protruding semiconductor fin 20″. The protruding semiconductor fin 20″ is further over a bulk semiconductor substrate.

Next, as also shown in FIG. 6A, bond layer 130 is formed. Differing from the structure shown in FIG. 3E, in which a metal line (an inter-metal) is formed in lower wafer 2, in the lower wafer 2 as shown in FIG. 6A, no horizontal metal line is formed over transistor 10L.

FIG. 6B illustrates the bonding of carrier 136 to bond layer 130. In accordance with some embodiments, carrier 136 includes semiconductor substrate 134, which may be a silicon substrate. Bond layer 132 is formed on semiconductor substrate 134. The bonding of bond layer 132 to bond layer 130 may be through fusion bonding in accordance with some embodiments. In accordance with alternative embodiments, carrier 136 includes a transparent substrate (also denoted using reference numeral 134) such as a glass carrier, which is attached to lower wafer 2 through an adhesive such as an LTHC material (also denoted using reference numeral 132).

The structure including lower wafer 2 and carrier 136 is then flipped upside down, and the resulting structure is shown in FIG. 6C. Substrate 20 is then removed, for example, in a smart cut process, a CMP process, a mechanical grinding process, and/or an anisotropic etching process. The protruding semiconductor fin 20″ and source/drain regions 50L in the lower transistor 10L are thus exposed. A bond layer 68L (FIG. 6D) is then formed as a top surface layer of wafer 2.

Further referring to FIG. 6D, wafer 102 is bonded to wafer 2 through fusion bonding. Wafer 102 may be essentially the same as discussed in preceding embodiments, and the details are not repeated herein.

Next, as shown in FIG. 6E, transistor 10U is formed. In accordance with some embodiments, transistor 10U includes semiconductor nanostructures 26U forming the channels, source/drain regions 50U, and gate stacks 60U wrapping around the semiconductor nanostructures 26U. Transistor 10U may have an opposite conductivity type than transistor 10L. The conductivity type of source/drain regions 50U may be opposite to that of source/drain regions 50L.

Next, further referring to FIG. 6E, contact plug 71 is formed. Contact plug 71 is electrically connected to one of source/drain regions 50U, and is landed on the top surface of the source/drain region 50U. There may be a silicide region (not shown) between and contacting contact plug 71 and source/drain region 50U.

Deep contact plug 70 is also formed, and penetrates through one of source/drain region 50U, and lands on the source/drain region 50L. Deep contact plug 70 acts as both of the source/drain contact plug and the deep via (local interconnect) interconnecting source/drain regions 50U and 50L. There may be source/drain silicide regions (not shown) formed between deep contact plug 70 and source/drain region 50U, and between deep contact plug 70 and source/drain region 50L.

FIG. 6E also illustrates the formation of vias 76 and metal lines 80, which are formed in dielectric layers 72, 74, and 78. Bond layer 82 is also formed, and may be planarized.

FIG. 6F illustrates the bonding of carrier 88 to bond layer 82, thus forming composite wafer 104. The resulting composite wafer 104 is then flipped upside down, and the resulting structure is shown in FIG. 6G.

Carrier 136 is then removed, and the resulting structure is shown in FIG. 6H. In accordance with some embodiments in which carrier 136 is bonded to bond layer 130 through fusion bonding, the removal of carrier 136 may include a smart cut process, a CMP process, a mechanical grinding process, and/or an anisotropic etching process. Otherwise, a laser beam may be used to de-bond carrier 136 from the underlying structure. Bond layer 130 is also removed, and lower transistor 10L is thus exposed.

FIG. 6I illustrates the formation of additional features including source/drain contact plugs 59, and an interconnect structure including via 65 and the corresponding dielectric layers. The interconnect structure may also include metal lines 110. Although not illustrated, there may be metal silicide regions formed between source/drain contact plugs 59 and source/drain regions 50L. A source/drain contact plug 59 is thus electrically connected to one of source/drain regions 50U through a corresponding source/drain region 50L, and through deep contact plug 70. Differing from the embodiments in FIG. 1N, in which both of the source/drain regions 50L and 50U are penetrated-through in order to provide the electrical paths through them, one of source/drain regions 50L (illustrated on the right side of FIG. 6I) is used to provide through-connection.

In subsequent processes, more layers/features may be formed, and the resulting composite wafer 104 may be sawed into dies. In the resulting dies obtained from the singulated composite wafer 104, the deep contact plug 70 acts as a part of the local interconnect for interconnecting source/drain regions 50L and 50U.

In the embodiments formed through sequential formation processes, the upper transistor is formed based on the semiconductor materials of an upper wafer, and the formation of the upper transistor is performed after the upper wafer is bonded to the lower wafer. Since the selection of the structure and the material of the upper wafer has flexibility, the semiconductor materials for forming the channels of the upper transistors and the lower transistors may be selected separately based on the conductivity types of the respective transistors, and may have different surface orientations. For example, the surface orientation of the p-type transistors may be selected as being (110), while the surface orientation of the n-type transistors may be selected as being (100), so that the performance of both of the upper transistors and the lower transistors are optimized. Also, the upper transistors and the lower transistors may have different numbers of semiconductor nanostructures. In addition, it is possible to form the upper transistors and lower transistors as different types of transistors (such as GAA transistors and FinFETs).

The embodiments of the present disclosure have some advantageous features. By adopting parallel formation process or sequential formation process, the design of the upper transistors and lower transistors may have more flexibility such as in selecting different crystal orientations of the channels, different numbers of nanostructures, etc., The upper transistor and the lower transistor may also be different types of transistor such as GAA transistors or FinFETs. Also, inter-metal may be formed between the upper transistors and the lower transistors to provide more routing ability.

In accordance with some embodiments of the present disclosure, a method comprises forming a lower transistor in a lower wafer, wherein the lower transistor comprises a lower source/drain region; forming a contact plug electrically connecting to the lower source/drain region; forming a metal line over the lower transistor and as a part of the lower wafer, wherein a first portion of the metal line is vertically aligned to the lower source/drain region; bonding an upper wafer to the lower wafer; forming an upper transistor in the upper wafer, wherein the upper transistor comprises an upper source/drain region, and the upper source/drain region is vertically aligned to a second portion of the metal line, and wherein the upper transistor and the lower transistor collectively form a CFET; forming a first interconnect structure on the lower wafer and electrically connecting to the lower transistor; and forming a second interconnect structure on the upper wafer and electrically connecting to the upper transistor.

In an embodiment, the method further comprises, after the upper transistor is formed, forming a deep contact plug penetrating through the lower source/drain region, wherein the deep contact plug contacts the metal line and electrically connects the lower source/drain region to the metal line. In an embodiment, the lower transistor comprises a semiconductor substrate, and the method further comprises removing the semiconductor substrate to reveal the lower source/drain region, wherein the deep contact plug is formed after the semiconductor substrate is removed. In an embodiment, the first interconnect structure is formed after the deep contact plug is formed. In an embodiment, the method further comprises forming a via, wherein the metal line is connected to the contact plug through the via.

In an embodiment, the method further comprises forming a etch stop layer over the lower transistor; forming a dielectric layer over and contacting the etch stop layer; etching the dielectric layer to form a first trench, wherein the etching is stopped on the etch stop layer, and a first side of the etch stop layer is exposed; and etching-through the etch stop layer from the first side, wherein the metal line is formed in the first trench. In an embodiment, the contact plug is a deep contact plug, and the forming the contact plug further comprises etching-through the lower source/drain region and an inter-layer dielectric in the lower wafer to form a second trench, wherein a second side of the etch stop layer opposing the first side of the etch stop layer is exposed to the second trench; and etching-through the etch stop layer from the second side to reveal the metal line, wherein the deep contact plug is formed in the second trench.

In an embodiment, the method further comprises forming a first bond layer over the metal line and as a part of the lower wafer, wherein the upper wafer comprises a second bond layer bonding to the first bond layer; and removing an additional semiconductor substrate of the upper wafer to reveal a multi-layer stack, wherein the upper transistor is formed based on the multi-layer stack. In an embodiment, the method further comprises, after the upper transistor is formed, forming a deep contact plug penetrating through the upper source/drain region, wherein the deep contact plug contacts the metal line and electrically connects the upper source/drain region to the metal line.

In an embodiment, the upper wafer is bonded to the lower wafer through a face-to-back bonding process. In an embodiment, the upper wafer is bonded to the lower wafer through a back-to-back bonding process. In an embodiment, each of the lower transistor and the upper transistor comprises a transistor selected from a gate-all-around transistor and a fin field-effect transistor.

In accordance with some embodiments of the present disclosure, a structure comprises a lower transistor comprising a lower source/drain region; a contact plug electrically connecting to the lower source/drain region; an upper transistor overlapping the lower transistor, wherein the upper transistor comprises an upper source/drain region, and the upper source/drain region is vertically offset from the lower source/drain region; an electrical path electrically connecting the lower source/drain region to the upper source/drain region; a first interconnect structure electrically connecting to the lower transistor; and a second interconnect structure electrically connecting to the upper transistor, wherein the first interconnect structure and the second interconnect structure are on opposing sides of a combined structure comprising the lower transistor and the upper transistor.

In an embodiment, the electrical path comprises a metal line between the lower transistor and the upper transistor. In an embodiment, the metal line comprises a first portion overlapping the lower source/drain region, and a second portion overlapped by the upper source/drain region. In an embodiment, the structure further comprises a first deep contact plug penetrating through the lower source/drain region; and a second deep contact plug penetrating through the upper source/drain region, wherein the lower source/drain region is electrically connected to the upper source/drain region through the first deep contact plug, the metal line, and the second deep contact plug. In an embodiment, the structure further comprises an etch stop layer underlying and contacting the metal line, wherein the first deep contact plug penetrates through the etch stop layer, and the metal line contacts the etch stop layer to form a horizontal interface.

In accordance with some embodiments of the present disclosure, a structure comprises complementary field-effect transistors comprising a lower transistor comprising a lower source/drain region; and an upper transistor overlapping the lower transistor, wherein the upper transistor comprises an upper source/drain region that is vertically misaligned from the lower source/drain region; a horizontal metal line between the lower transistor and the upper transistor, wherein the horizontal metal line connects the lower source/drain region to the upper source/drain region; a lower contact plug contacting a bottom surface of the horizontal metal line, wherein the lower contact plug connects the horizontal metal line to the lower source/drain region; and an upper contact plug contacting a top surface of the horizontal metal line, wherein the upper contact plug connects the horizontal metal line to the upper source/drain region.

In an embodiment, the lower contact plug penetrates through the lower source/drain region, and the upper contact plug penetrates through the upper source/drain region. In an embodiment, the structure further comprises an etch stop layer contacting the horizontal metal line to form a horizontal interface, wherein the upper contact plug penetrates through the etch stop layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a lower transistor in a lower wafer, wherein the lower transistor comprises a lower source/drain region;
forming a contact plug electrically connecting to the lower source/drain region;
forming a metal line over the lower transistor and as a part of the lower wafer, wherein a first portion of the metal line is vertically aligned to the lower source/drain region;
bonding an upper wafer to the lower wafer;
forming an upper transistor in the upper wafer, wherein the upper transistor comprises an upper source/drain region, and the upper source/drain region is vertically aligned to a second portion of the metal line, and wherein the upper transistor and the lower transistor collectively form a CFET;
forming a first interconnect structure on the lower wafer and electrically connecting to the lower transistor; and
forming a second interconnect structure on the upper wafer and electrically connecting to the upper transistor.

2. The method of claim 1 further comprising, after the upper transistor is formed, forming a deep contact plug penetrating through the lower source/drain region, wherein the deep contact plug contacts the metal line and electrically connects the lower source/drain region to the metal line.

3. The method of claim 2, wherein the lower transistor comprises a semiconductor substrate, and the method further comprise:
removing the semiconductor substrate to reveal the lower source/drain region, wherein the deep contact plug is formed after the semiconductor substrate is removed.

4. The method of claim 2, wherein the first interconnect structure is formed after the deep contact plug is formed.

5. The method of claim 1 further comprising:
forming a via, wherein the metal line is connected to the contact plug through the via.

6. The method of claim 1 further comprising:
forming a etch stop layer over the lower transistor;
forming a dielectric layer over and contacting the etch stop layer;
etching the dielectric layer to form a first trench, wherein the etching is stopped on the etch stop layer, and a first side of the etch stop layer is exposed; and
etching-through the etch stop layer from the first side, wherein the metal line is formed in the first trench.

7. The method of claim 6, wherein the contact plug is a deep contact plug, and the forming the contact plug further comprises:
etching-through the lower source/drain region and an inter-layer dielectric in the lower wafer to form a second trench, wherein a second side of the etch stop layer opposing the first side of the etch stop layer is exposed to the second trench; and
etching-through the etch stop layer from the second side to reveal the metal line, wherein the deep contact plug is formed in the second trench.

8. The method of claim 1 further comprising:
forming a first bond layer over the metal line and as a part of the lower wafer, wherein the upper wafer comprises a second bond layer bonding to the first bond layer; and
removing an additional semiconductor substrate of the upper wafer to reveal a multi-layer stack, wherein the upper transistor is formed based on the multi-layer stack.

9. The method of claim 1 further comprising, after the upper transistor is formed, forming a deep contact plug penetrating through the upper source/drain region, wherein the deep contact plug contacts the metal line and electrically connects the upper source/drain region to the metal line.

10. The method of claim 1, wherein the upper wafer is bonded to the lower wafer through a face-to-back bonding process.

11. The method of claim 1, wherein the upper wafer is bonded to the lower wafer through a back-to-back bonding process.

12. The method of claim 1, wherein each of the lower transistor and the upper transistor comprises a transistor selected from a gate-all-around transistor and a fin field-effect transistor.

13. A structure comprising:
a lower transistor comprising a lower source/drain region;
a contact plug electrically connecting to the lower source/drain region;
an upper transistor overlapping the lower transistor, wherein the upper transistor comprises an upper source/drain region, and the upper source/drain region is vertically offset from the lower source/drain region;
an electrical path electrically connecting the lower source/drain region to the upper source/drain region;
a first interconnect structure electrically connecting to the lower transistor; and
a second interconnect structure electrically connecting to the upper transistor, wherein the first interconnect structure and the second interconnect structure are on opposing sides of a combined structure comprising the lower transistor and the upper transistor.

14. The structure of claim 13, wherein the electrical path comprises a metal line between the lower transistor and the upper transistor.

15. The structure of claim 14, wherein the metal line comprises a first portion overlapping the lower source/drain region, and a second portion overlapped by the upper source/drain region.

16. The structure of claim 14 further comprising:
a first deep contact plug penetrating through the lower source/drain region; and
a second deep contact plug penetrating through the upper source/drain region, wherein the lower source/drain region is electrically connected to the upper source/drain region through the first deep contact plug, the metal line, and the second deep contact plug.

17. The structure of claim 16 further comprising:
an etch stop layer underlying and contacting the metal line, wherein the first deep contact plug penetrates through the etch stop layer, and the metal line contacts the etch stop layer to form a horizontal interface.

18. A structure comprising:
complementary field-effect transistors comprising:
a lower transistor comprising a lower source/drain region; and
an upper transistor overlapping the lower transistor, wherein the upper transistor comprises an upper source/drain region that is vertically misaligned from the lower source/drain region;
a horizontal metal line between the lower transistor and the upper transistor, wherein the horizontal metal line connects the lower source/drain region to the upper source/drain region;
a lower contact plug contacting a bottom surface of the horizontal metal line, wherein the lower contact plug connects the horizontal metal line to the lower source/drain region; and
an upper contact plug contacting a top surface of the horizontal metal line, wherein the upper contact plug connects the horizontal metal line to the upper source/drain region.

19. The structure of claim 18, wherein the lower contact plug penetrates through the lower source/drain region, and the upper contact plug penetrates through the upper source/drain region.

20. The structure of claim 18 further comprising an etch stop layer contacting the horizontal metal line to form a horizontal interface, wherein the upper contact plug penetrates through the etch stop layer.
